(19) United States
(12) Patent Application Publication
(10) Pub. No.: US 2012/0133061 A1
(43) Pub. Date: May 31, 2012

(54) PHOTOSENSITIVE ADHESIVE, AND FILM ADHESIVE, ADHESIVE SHEET, ADHESIVE PATTERN, SEMICONDUCTOR WAFER WITH ADHESIVE LAYER, AND SEMICONDUCTOR DEVICE, WHICH ARE MADE USING SAME

(76) Inventors: Kazuyuki Mitsukura, Tsukuba-shi (JP); Takashi Kawamori, Tsukuba-shi (JP); Takashi Masuko, Tsukuba-shi (JP); Shigeki Katogi, Hitachi-shi (JP)

(21) Appl. No.: 13/380,349

(22) PCT Filed: Jun. 28, 2010
(86) PCT No.: PCT/JP2010/060988

§ 371 Date: Feb. 15, 2012

(30) Foreign Application Priority Data
Jun. 30, 2009 (JP) 2009-155526

(51) Int. Cl. H01L 23/12; C09J 179/02; B32B 3/10; C09J 163/00; B32B 27/38

(52) U.S. Cl. 257/798; 522/111; 428/345; 428/195.1; 257/E23.003

(57) ABSTRACT

To provide a photosensitive adhesive which is sufficiently excellent in terms of all the properties of attachment, pattern formability, thermocompression bondability and high-temperature adhesion, and which has thermocompression bondability for adherends after patterning by exposure and development, and is capable of alkali development, as well as a film adhesive, an adhesive sheet, an adhesive pattern, a semiconductor wafer with an adhesive layer and a semiconductor device, which employ the same. A photosensitive adhesive comprising (A) an imide group-containing resin with a fluoroalkyl group, (B) a radiation-polymerizable compound, (C) a photoinitiator and (D) a thermosetting component.

### TECHNICAL FIELD

The present invention relates to a photosensitive adhesive, and to a film adhesive, an adhesive sheet, an adhesive pattern, a semiconductor wafer with an adhesive layer and a semiconductor device, which are made using it.

### BACKGROUND ART

Various forms of semiconductor packages have been proposed in recent years to meet higher performance and function demands for electronic parts. In such semiconductor packages, the adhesive used for bonding between the semiconductor element and the semiconductor element-mounting supporting member is preferably one with an excellent attachment property when formed into a film (hereunder referred to simply as “attachment property”), and that when cured, exhibits excellent adhesion at high temperature, thermocompression bondability, heat resistance and reflow resistance (hereunder referred to simply as “high-temperature adhesion”, “thermocompression bondability” and “reflow resistance”, respectively). In order to simplify the assembly process for a semiconductor package, the adhesive is preferably one with excellent pattern formability including thinning and soluble developability, with alkali developing solutions (hereunder referred to simply as “pattern formability”).

A photosensitive adhesive composition has the function of “photosensitivity”, whereby sections irradiated with light are chemically altered to become insolubilized or solubilized in aqueous solutions or organic solvents, and therefore using such a photosensitive adhesive composition as the adhesive and exposing it through a photomask for development can yield a high-definition adhesive pattern.

As photosensitive adhesive compositions there are already known photoresists and polyimide resin precursor (polyamide acid)-based compositions (Patent documents 1-3), as well as low-Tg polyimide resin-based compositions (Patent document 4).

### CITATION LIST

### Patent Literature

[Patent document 1] Japanese Unexamined Patent Application Publication No. 2000-290501
[Patent document 2] Japanese Unexamined Patent Application Publication No. 2001-329233
[Patent document 3] Japanese Unexamined Patent Application Publication HEI No. 11-24257
[Patent document 4] International Patent Publication No. WO 07/004,569.

### SUMMARY OF INVENTION

### Technical Problem

However, photoresists have been inadequate in terms of heat resistance. Also, photosensitive adhesive compositions based on polyimide resin precursors, while being adequate in terms of heat resistance, require high temperatures of 300° C. or higher during thermal cyclizing imidation, and they have therefore been less than adequate in terms of significant thermal damage on surrounding materials, large volatilizing component amounts and susceptibility to thermal stress.

In addition, these prior art photosensitive adhesive compositions have been in need of improvement because they do not easily exhibit both an attachment property and pattern formability, and are also inadequate in terms of high-temperature adhesion and thermocompression bondability.

Furthermore, photosensitive adhesive compositions based on the aforementioned low-Tg polyimide resins exhibit sufficient attachment properties but are inadequate in terms of pattern formability, thermocompression bondability and high-temperature adhesion.

In order to improve the pattern formability, thermocompression bondability and high-temperature adhesion of photosensitive adhesive compositions, it has been attempted to adjust the amount of radiation-polymerizable compound or thermosetting resin. However, increasing the amount of radiation-polymerizable compound tends to increase the tack (stickiness or adhesive property) rendering handling more difficult, and tends to result in inadequate thermocompression bondability and increased stress. On the other hand, reducing the radiation-polymerizable compound tends to result in inadequate pattern formability and high-temperature adhesion. Furthermore, increasing the amount of thermosetting resin tends to result in inadequate pattern formability.

Also, when the Tg of the polyimide is increased for greater high-temperature adhesion, the cohesion between polyimide molecules increases, and penetration of the developing solution during development is inhibited resulting in notably impaired pattern formability, and making it impossible to form thin patterns. In such cases, the unexposed sections become detached from the adherend as films, so that a pattern is formed (detaching development). In this developed state, the film-like unexposed sections remain for long periods in the developing solution, becoming re-attached to the pattern-forming sections and problematically lowering the semiconductor device yield.

Thus, no photosensitive adhesive composition has existed in the prior art that is sufficiently excellent in terms of all the properties of attachment, pattern formability, thermocompression bondability and high-temperature adhesion, and the development of such a photosensitive adhesive composition has been desired.

It is therefore an object of the present invention to provide a photosensitive adhesive composition which is sufficiently excellent in terms of all the properties of attachment, pattern formability, thermocompression bondability and high-temperature adhesion, as well as a film adhesive, an adhesive sheet, an adhesive pattern, a semiconductor wafer with an adhesive layer and a semiconductor device, which employ the same.

### Solution to Problem

Specifically, the invention provides a photosensitive adhesive comprising (A) an imide group-containing resin with a fluoroalkyl group (hereunder also referred to as “component (A)”), (B) a radiation-polymerizable compound (hereunder also referred to as “component (B)”), (C) a photoinitiator (hereunder also referred to as “component (C)”) and (D) a thermosetting component (hereunder also referred to as “component (D)”). The photosensitive adhesive of the invention having such a construction is sufficiently excellent in terms of all the properties of attachment, pattern formability, thermocompression bondability and high-temperature adhesion. In particular, the photosensitive adhesive of the invention, comprising component (A) (an imide group-containing resin with a fluoroalkyl group) has limited increase in cohesion between the imide group-containing molecules when the Tg of the imide group-containing is high, and therefore the pattern formability (soluble developability and thinning), thermocompression bondability and high-temperature adhesion are excellent.

A fluoroalkyl group is a compound having a C—F bond.

For the photosensitive adhesive composition of the invention, “attachment property” refers to the attachment property when the photosensitive adhesive composition is formed into a film and used as a film adhesive, “high-temperature adhesion” refers to the adhesion under heating, when the photosensitive adhesive composition has been cured, “pattern formability” refers to the precision of the adhesive pattern obtained upon exposing an adhesive layer made of the film adhesive on an adhered through a photomask and development by the alkali developing solution, and “thermocompression bondability” refers to the degree of bonding when the adhesive pattern has been contact bonded (thermocompression bonded) to a supporting member or the like under heating.

The Tg of component (A) in the photosensitive adhesive composition of the invention is preferably no higher than 180° C. from the viewpoint of the attachment property and thermocompression bondability.

The (A) imide group-containing resin with a fluoroalkyl group in the photosensitive adhesive composition of the invention preferably also has an alkali-soluble group, from the viewpoint of pattern formability.

The component (A) in the photosensitive adhesive composition of the invention is preferably an imide group-containing resin obtained by reacting a tetracarboxylic dianhydride with a diamine containing a diamine with a phenolic hydroxyl group at 5 mol % or greater of the total diamine, from the viewpoint of pattern formability, thermocompression bondability and high-temperature adhesion.

The excellent properties obtained when using a phenolic hydroxyl-containing diamine as the diamine are attributed to the following reason. When a photosensitive adhesive composition is coated and worked into a film adhesive by heat drying, using a carboxyl group-containing resin as the imide group-containing resin causes reaction with the added epoxy resin during heat drying, thereby significantly lowering the acid value of the thermoplastic resin. In contrast, if the side chains of the imide group-containing resin are phenolic hydroxyl groups, the reaction with the epoxy resin proceeds less easily than when they are carboxyl groups. As a result, the pattern formability, thermocompression bondability and high-temperature adhesion are improved.

The diamine with a phenolic hydroxyl in the photosensitive adhesive composition of the invention preferably comprises a diphenol diamine with a fluoroalkyl group, represented by the following formula (6), from the viewpoint of pattern formability, thermocompression bondability and reflow resistance.

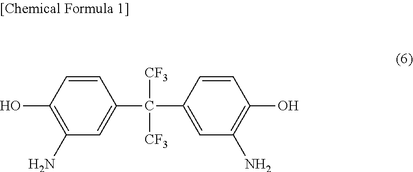

The “reflow resistance” referred to here is the reflow resistance after the adhesive pattern has been thermocompression bonded onto a supporting member or the like, cured and absorbed of moisture.

The (D) thermosetting component in the photosensitive adhesive composition of the invention preferably contains (D1) an epoxy resin, from the viewpoint of storage stability and high-temperature adhesion.

The (A) imide group-containing resin in the photosensitive adhesive composition of the invention is preferably an alkali-soluble resin, from the viewpoint of pattern formability.

From the viewpoint of thermocompression bondability, high-temperature adhesion and reflow resistance, the (D) thermosetting component in the photosensitive adhesive composition of the invention preferably further contains (D2) a compound with an ethylenic unsaturated group and an epoxy group.

The improved properties of high-temperature adhesion and reflow resistance by addition of (D2) are attributed, for example, to the following reason. When a (meth)acrylate with an epoxy group (component (D2)) is introduced into a network between photoirradiated radiation-polymerizable compounds, the apparent crosslink density is reduced and the thermocompression bondability is increased. In addition, when the epoxy groups react with thermosetting groups or a curing agent, and especially with phenolic hydroxyl groups on polymer side chains, entanglement between molecular chains increases, forming a network that is tougher than a system in which a radiation-polymerizable compound and a thermosetting resin are simply combined and the individual crosslinking reactions take place independently. As a result, sufficient excellent in terms of high-temperature adhesion and humidity resistance is achieved.

The (D) thermosetting component in the photosensitive adhesive composition of the invention preferably further contains (D3) a phenol compound, from the viewpoint of high-temperature adhesion and pattern formability.

The photosensitive adhesive composition of the invention preferably further comprises (E) a peroxide, from the viewpoint of high-temperature adhesion, reflow resistance and hermetic sealability.

The photosensitive adhesive composition of the invention also preferably further comprises (F) a filler, from the viewpoint of film formability.

Another aspect of the invention relates to a film adhesive obtained by forming the aforementioned photosensitive adhesive composition of the invention into a film. The film adhesive of the invention employs a photosensitive adhesive composition, thereby resulting in a sufficiently excellent film in terms of all the properties of attachment, high-temperature adhesion, pattern formability, thermocompression bondability, heat resistance and humidity resistance. In particular, the film adhesive has an excellent attachment property at low temperatures as well (low-temperature attachment property).

The present invention further relates to an adhesive sheet comprising a base and an adhesive layer composed of the aforementioned film adhesive formed on the base.

The invention still further relates to an adhesive pattern that is obtained by exposing an adhesive layer composed of the aforementioned film adhesive laminated on an adherend, through a photomask, and developing the exposed adhesive layer with an alkali developing solution. The adhesive pattern of the invention may also be formed by direct pattern-rendering exposure of an adhesive layer composed of the aforementioned film adhesive laminated on an adherend, using a direct writing exposure technique, and developing the exposed adhesive layer with an aqueous alkali solution. The adhesive pattern of the invention, which employs the aforementioned photosensitive adhesive composition, is a high-definition pattern with excellent thermocompression bondability. In particular, the adhesive pattern has excellent thermocompression bondability at low temperature (low-temperature thermocompression bondability).

The invention still further relates to a semiconductor wafer with an adhesive layer, that comprises a semiconductor wafer and an adhesive layer composed of the aforementioned film adhesive, laminated on the semiconductor wafer.

The invention still further relates to a semiconductor device having a structure in which semiconductor elements, and/or a semiconductor element and a semiconductor element-mounting supporting member, are bonded using the photosensitive adhesive composition. The semiconductor device of the invention, employing the photosensitive adhesive composition described above, is also adequately suitable for simplifying the production process, and has excellent reliability.

The semiconductor element-mounting supporting member is preferably a transparent base.

### Advantageous Effects of Invention

According to the invention it is possible to provide a photosensitive adhesive composition that is sufficiently excellent in terms of all of the properties of attachment (low-temperature attachment), high-temperature adhesion, pattern formability and thermocompression bondability (low-temperature thermocompression bondability).

Also according to the invention, it is possible to provide a fine pattern with thermocompression bondability and high-temperature adhesion, and a material with excellent reflow resistance.

Furthermore, since pattern formability can be maintained according to the invention even when the imide group-containing resin has a high Tg, it is possible to provide a material with excellent high-temperature adhesion and hermetic sealability when a frame-like pattern has been formed.

In addition, the invention can provide a film adhesive, an adhesive sheet, an adhesive pattern, a semiconductor wafer with an adhesive layer and a semiconductor device, which have excellent attachment property (low-temperature attachment property), high-temperature adhesion, pattern formability, thermocompression bondability (low-temperature thermocompression bondability), reflow resistance and hermetic sealability.

The “hermetic sealability” referred to here is the condensation resistance (cloudiness resistance) after the frame-like pattern of the adhesive has been thermocompression bonded onto a supporting member or the like, cured and absorbed of moisture.

### BRIEF DESCRIPTION OF DRAWINGS

FIG. 1 is an end view showing an embodiment of a film adhesive of the invention.

FIG. 2 is an end view showing an embodiment of an adhesive sheet of the invention.

FIG. 3 is an end view showing an embodiment of an adhesive sheet of the invention.

FIG. 4 is an end view showing an embodiment of an adhesive sheet of the invention.

FIG. 5 is a top view showing an embodiment of a semiconductor wafer with an adhesive layer according to the invention.

FIG. 6 is an end view of FIG. 5 along line IV-IV.

FIG. 7 is a top view showing an embodiment of an adhesive pattern according to the invention.

FIG. 8 is an end view of FIG. 7 along line V-V.

FIG. 9 is a top view showing an embodiment of an adhesive pattern according to the invention.

FIG. 10 is an end view of FIG. 9 along line VI-VI.

FIG. 11 is an end view showing an embodiment of a semiconductor device according to the invention.

FIG. 12 is an end view showing an embodiment of a semiconductor device according to the invention.

FIG. 13 is an end view of an embodiment of a method for manufacturing a semiconductor device according to the invention.

FIG. 14 is an end view of an embodiment of a method for manufacturing a semiconductor device according to the invention.

FIG. 15 is a plan view of an embodiment of a method for manufacturing a semiconductor device according to the invention.

FIG. 16 is an end view of an embodiment of a method for manufacturing a semiconductor device according to the invention.

FIG. 17 is an end view of an embodiment of a method for manufacturing a semiconductor device according to the invention.

FIG. 18 is an end view of an embodiment of a method for manufacturing a semiconductor device according to the invention.

FIG. 19 is an end view of an embodiment of a method for manufacturing a semiconductor device according to the invention.

FIG. 20 is an end view showing an embodiment of a semiconductor device according to the invention.

FIG. 21 is an end view of an embodiment of a method for manufacturing a semiconductor device according to the invention.

FIG. 22 is an end view of an embodiment of a method for manufacturing a semiconductor device according to the invention.

FIG. 23 is an end view of an embodiment of a method for manufacturing a semiconductor device according to the invention.

FIG. 24 is an end view of an embodiment of a method for manufacturing a semiconductor device according to the invention.

FIG. 25 is an end view of an embodiment of a method for manufacturing a semiconductor device according to the invention.

FIG. 26 is an end view of an embodiment of a semiconductor device according to the invention.

FIG. 27 is an end view showing an example of a CMOS sensor employing the semiconductor element shown in FIG. 26 as a solid pickup element.

### DESCRIPTION OF EMBODIMENTS

Preferred embodiments for carrying out the invention will now be explained in detail, with reference to the accompanying drawings as necessary. However, the present invention is not limited to the embodiments described below. Throughout the drawings, corresponding elements will be referred to by like reference numerals and will be explained only once. Unless otherwise specified, the vertical and horizontal positional relationships are based on the positional relationships in the drawings, and the dimensional proportions in the drawing are not limited to the illustrated dimensions.

The photosensitive adhesive composition of this embodiment comprises (A) an imide group-containing resin with a fluoroalkyl group, (B) a radiation-polymerizable compound, (C) a photoinitiator and (D) a thermosetting component.

The Tg of component (A) is preferably no higher than 180° C., and more preferably no higher than 120° C. If the Tg exceeds 180° C., a high temperature will be necessary to attach the film adhesive (adhesive layer) to the adherend (semiconductor wafer), and warping will tend to occur more easily in the semiconductor wafer. The attachment temperature for a film adhesive onto a wafer back side is preferably 20-150° C. and more preferably 40-100° C., from the viewpoint of inhibiting warping of the semiconductor wafer. Also, when the Tg is 180° C. or higher, an even higher temperature will be necessary for thermocompression bonding after pattern formation. The thermocompression bonding temperature is preferably 60-220° C. and more preferably 100-180° C., from the viewpoint of promoting the thermosetting reaction before thermocompression bonding and inhibiting warping of the semiconductor wafer. In order to allow attachment and thermocompression bonding at the aforementioned temperature, the Tg of the film adhesive is preferably no higher than 180° C., more preferably no higher than 150° C. and even more preferably no higher than 120° C. On the other hand, the Tg is preferably 20° C. or higher, more preferably 40° C. or higher and even more preferably 50° C. or higher. If the Tg is below 20° C., the tack of the film surface at the B-stage state will be too strong, tending to result in unsatisfactory manageability. Also, the Tg of the thermoset product after exposure will tend to be lowered, and the high-temperature adhesion, reflow resistance and hermetic sealability will tend to be reduced.

The “Tg” referred to here is the primary dispersion peak temperature when component (A) has been formed into a film. The primary dispersion peak temperature is obtained as the tan δ peak temperature, measured using an “RSA-2” viscoelasticity analyzer (trade name) by Rheometrix, under conditions with a temperature-elevating rate of 5° C./min, a frequency of 1 Hz and a measuring temperature of between −50 and 300° C.

The weight-average molecular weight of component (A) is preferably controlled to within the range of 5000-500,000, more preferably 10,000-300,000, and even more preferably 10,000-100,000. If the weight-average molecular weight is within this range, the strength, pliability and tack properties of the photosensitive adhesive composition formed into a sheet or film will be satisfactory, while the hot flow property will also be satisfactory, thus helping to ensure good embedding properties for wiring levels (concavoconvexities) on base surfaces. If the weight-average molecular weight is less than 5000, the film formability will tend to be insufficient. On the other hand, if the weight-average molecular weight is greater than 500,000, the hot flow property and embedding property will tend to be insufficient, or the solubility of the resin composition for the alkali developing solution during pattern formation will tend to be insufficient. The “weight-average molecular weight” referred to here is the weight-average molecular weight measured in terms of polystyrene using a “C-R4A” high-performance liquid chromatograph (trade name) by Shimadzu Corp.

If the Tg and weight-average molecular weight of component (A) are within these ranges, it will be possible to lower the attachment temperature onto wafers while also lowering the heating temperature for adhesive anchoring of the semiconductor element to the semiconductor element-mounting supporting member (thermocompression bonding temperature), and to limit increase in warping of the semiconductor element. It will also be possible to effectively impart an attachment property, thermocompression bondability and developability.

The imide group-containing resin of component (A) may be a polyimide resin, polyamideimide resin, polyetherimide resin, polyurethaneimide resin, polyurethaneamideimide resin, siloxanepolyimide resin, polyesterimide resin, or a copolymer thereof. Any of these may be used alone or in combinations of two or more. From the viewpoint of alkali solubility, an ethylene oxide or propylene ether skeleton is preferably present on the main chain and/or a side chain of these resins.

Component (A) may be obtained, for example, by condensation reaction of a tetracarboxylic dianhydride and diamine component by a known process. Specifically, the compositional ratio is adjusted so that the tetracarboxylic dianhydride and diamine are in equimolar amounts in the organic solvent, or if necessary so that the total of diamines is in the range of preferably 0.5-2.0 mol and more preferably 0.8-1.0 mol with respect to 1.0 mol as the total tetracarboxylic dianhydrides (with any desired order of addition of the components), and addition reaction is conducted with a reaction temperature of no higher than 80° C. and preferably 0-60° C. The viscosity of the reaction mixture will gradually increase as the reaction proceeds, forming polyamide acid as the polyimide resin precursor. In order to prevent reduction in the properties of the resin composition, the tetracarboxylic dianhydride is preferably one that has been subjected to recrystallizing purifying treatment with acetic anhydride.

If the total diamines exceed 2.0 mol with respect to 1.0 mol as the total tetracarboxylic dianhydrides, in the compositional ratio of the tetracarboxylic dianhydride and diamine components for the condensation reaction, the amount of amine-terminal polyimide oligomers in the obtained polyimide resin will tend to be greater and the weight-average molecular weight of the polyimide resin will be reduced, such that the various properties of the resin composition, including the heat resistance, will tend to be inadequate. On the other hand, if the total diamines are less than 0.5 mol with respect to 1.0 mol as the total tetracarboxylic dianhydrides, the amount of acid-terminal polyimide resin oligomers will tend to be greater and the weight-average molecular weight of the polyimide resin will be reduced, such that the various properties of the resin composition, including the heat resistance, will tend to be inadequate.

The polyimide resin may be obtained by dehydrating cyclization of the reaction product (polyamide acid). Dehydrating cyclization can be accomplished by thermal cyclization using heat treatment or by chemical cyclization using a dehydrating agent.

The imide group-containing resin of component (A) is preferably a resin containing a structural unit represented by the following formula (A).

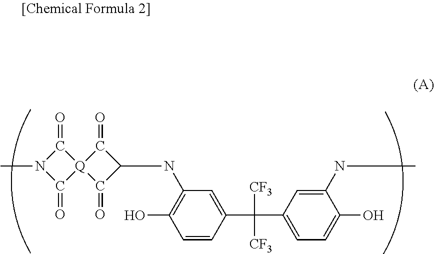

In formula (A), Q represents a tetravalent organic group, for example, a tetravalent organic group with a biphenyl skeleton, a tetravalent organic group with a naphthyl skeleton, a tetravalent organic group with a benzophenone skeleton, a tetravalent organic group with an alicyclic skeleton or a tetravalent organic group with a fluoroalkyl group.

Tetracarboxylic dianhydrides to be used as starting materials for the imide group-containing resin are not particularly restricted when a fluoroalkyl group is present in the diamine component, and from the viewpoint of lowering the linear expansion coefficient, for example, there are preferably used acid dianhydrides with biphenyl skeletons such as 3,3′,4,4′-biphenyltetracarboxylic dianhydride, 2,2′,3,3′-biphenyltetracarboxylic dianhydride, 2,3,3′,4′-biphenyltetracarboxylic dianhydride and 3,4,3′,4′-biphenyltetracarboxylic dianhydride, and acid dianhydrides with naphthyl skeletons such as 1,2,5,6-naphthalenetetracarboxylic dianhydride, 1,4,5,8-naphthalenetetracarboxylic dianhydride, 2,3,6,7-naphthalenetetracarboxylic dianhydride and 1,2,4,5-naphthalenetetracarboxylic dianhydride. From the viewpoint of allowing increase in the sensitivity during radiation curing, it is preferred to use an acid dianhydride with a benzophenone skeleton, such as 3,4,3′,4′-benzophenonetetracarboxylic dianhydride, 2,3,2′,3′-benzophenonetetracarboxylic dianhydride or 3,3,3′,4′-benzophenonetetracarboxylic dianhydride. From the viewpoint of allowing increase in transparency, it is preferred to use an acid dianhydride with an alicyclic skeleton, such as 1,2,3,4-butanetetracarboxylic dianhydride, decahydronaphthalene-1,4,5,8-tetracarboxylic dianhydride, 4,8-dimethyl-1,2,3,5,6,7-hexahydronaphthalene-1,2,5,6-tetracarboxylic dianhydride, cyclopentane-1,2,3,4-tetracarboxylic dianhydride, 1,2,3,4-cyclobutanetetracarboxylic dianhydride, bis(exo-bicyclo[2,2,1]heptane-2,3-dicarboxylic dianhydride or bicyclo-[2,2,2]-oct-7-ene-2,3,5,6-tetracarboxylic dianhydride, or an acid dianhydride with a fluoroalkyl group, such as 2,2-bis(3,4-dicarboxyphenyl)hexafluoropropane dianhydride, 2,2-bis[4-(3,4-dicarboxyphenyl)phenyl]hexafluoropropane dianhydride, 1,4-bis(2-hydroxyhexafluoroisopropyl)benzenebis(trimellitic anhydride) or 1,3-bis(2-hydroxyhexafluoroisopropyl)benzenebis(trimellitic anhydride). From the viewpoint of allowing increased transparency for 365 nm light, it is preferred to use a tetracarboxylic dianhydride represented by the following formula (1). In formula (1), a represents an integer of 2-20.

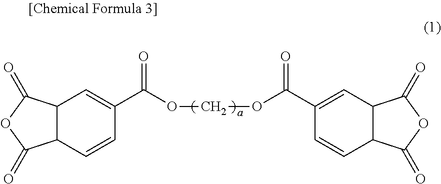

A tetracarboxylic dianhydride represented by formula (1) can be synthesized from trimellitic anhydride monochloride and its corresponding diol, for example, and specific examples include 1,2-(ethylene)bis(trimellitate anhydride), 1,3-(trimethylene)bis(trimellitate anhydride), 1,4-(tetramethylene)bis(trimellitate anhydride), 1,5-(pentamethylene)bis(trimellitate anhydride), 1,6-(hexamethylene)bis(trimellitate anhydride), 1,7-(heptamethylene)bis(trimellitate anhydride), 1,8-(octamethylene)bis(trimellitate anhydride), 1,9-(nonamethylene)bis(trimellitate anhydride), 1,10-(decamethylene)bis(trimellitate anhydride), 1,12-(dodecamethylene)bis(trimellitate anhydride), 1,16-(hexadecamethylene)bis(trimellitate anhydride) and 1,18-(octadecamethylene)bis(trimellitate anhydride). These compounds can lower the Tg without impairing the heat resistance.

As tetracarboxylic dianhydrides there are preferably used tetracarboxylic dianhydrides represented by the following formula (2) or (3), from the viewpoint of imparting satisfactory solubility in solvents or alkalis, as well as humidity resistance, transparency for 365 nm light, and thermocompression bondability.

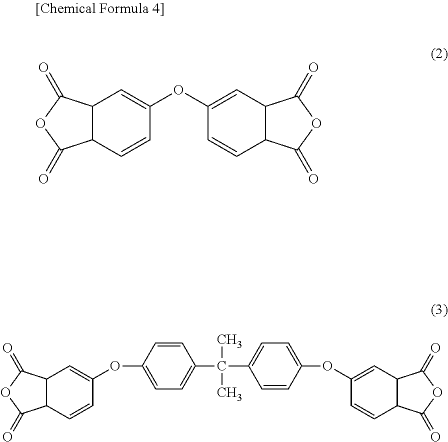

These tetracarboxylic dianhydrides may be used alone or in combinations of two or more.

When the diamine component does not contain a fluoroalkyl group, the tetracarboxylic dianhydride used as starting material for the imide group-containing resin may be a fluoroalkyl group-containing tetracarboxylic dianhydride such as 2,2-bis(3,4-dicarboxyphenyl)hexafluoropropane dianhydride, 2,2-bis[4-(3,4-dicarboxyphenyl)phenyl]hexafluoropropane dianhydride, 1,4-bis(2-hydroxyhexafluoroisopropyl)benzenebis(trimellitic anhydride), 1,3-bis(2-hydroxyhexafluoroisopropyl)benzenebis(trimellitic anhydride), 3,3′-diaminodiphenyldifluoromethane, 3,4′-diaminodiphenyldifluoromethane, 4,4′-diaminodiphenyldifluoromethane, 2,2-bis(3-aminophenyl)hexafluoropropane, 2,2-(3,4′-diaminodiphenyl)hexafluoropropane, 2,2-bis(4-aminophenyl)hexafluoropropane, 2,2-bis(4-(3-aminophenoxy)phenyl)hexafluoropropane or 2,2-bis(4-(4-aminophenoxy)phenyl)hexafluoropropane.

There are no particular restrictions on diamines to be used as starting materials for the imide group-containing resin, but the following diamines may be used to adjust the Tg and the solvent solubility and alkali solubility of the polymer. For example, from the viewpoint of allowing the heat resistance and adhesion to be improved, it is preferred to use o-phenylenediamine, m-phenylenediamine, p-phenylenediamine, bis(4-amino-3,5-dimethylphenyl)methane, bis(4-amino-3,5-diisopropylphenyl)methane, 2,2-bis(3-aminophenyl)propane, 2,2′-(3,4′-diaminodiphenyl)propane, 2,2-bis(4-aminophenyl)propane, 1,3-bis(3-aminophenoxy)benzene, 1,4-bis(3-aminophenoxy)benzene, 1,4-bis(4-aminophenoxy)benzene, 3,3′-(1,4-phenylenebis(1-methylethylidene))bisaniline, 3,4′-(1,4-phenylenebis(1-methylethylidene))bisaniline, 4,4′-(1,4-phenylenebis(1-methylethylidene))bisaniline, 2,2-bis(4-(3-aminophenoxy)phenyl)propane or 2,2-bis(4-aminophenoxyphenyl)propane. From the viewpoint of allowing the linear expansion coefficient to be reduced, it is preferred to use 3,3′-diaminodiphenyl ether, 3,4′-diaminodiphenyl ether, 4,4′-diaminodiphenyl ether, 3,3′-diaminodiphenylmethane, 3,4′-diaminodiphenylmethane, 4,4′-diaminodiphenylether methane, 3,3′-diaminodiphenylsulfone, 3,4′-diaminodiphenylsulfone, 4,4′-diaminodiphenylsulfone, bis(4-(3-aminoenoxy)phenyl)sulfone, bis(4-(4-aminoenoxy)phenyl)sulfone or 3,3′-dihydroxy-4,4′-diaminobiphenyl. From the viewpoint of allowing the adhesiveness with adherends such as metals to be increased, it is preferred to use 3,3′-diaminodiphenyl sulfide, 3,4′-diaminodiphenyl sulfide, 4,4′-diaminodiphenyl sulfide, bis(4-(3-aminoenoxy)phenyl)sulfide or bis(4-(4-aminoenoxy)phenyl)sulfide. For adjustment of the alkali solubility there may be used an aromatic diamine such as 3,5-diaminobenzoic acid, or 3,3′-dihydroxy-4,4′-diaminobiphenyl. Diamines that can lower the Tg include 1,3-bis(aminomethyl)cyclohexane, aliphatic etherdiamines represented by the following formula (8), and siloxanediamines represented by the following formula (9). In formula (8), R′, R² and R³ each independently represent a C1-10 alkylene group, and b represents an integer of 2-80. In formula (9), R⁴ and R⁹ each independently represent a C1-5 alkylene or an optionally substituted phenylene group, R⁵, R⁶, R⁷ and R⁸ each independently represent a C1-5 alkyl, phenyl or phenoxy group, and d represents an integer of 1-5.

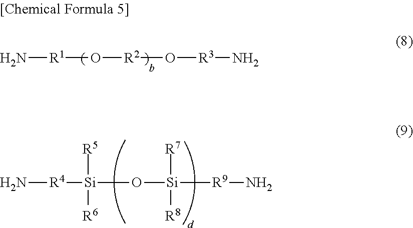

Preferred as diamine components, from the viewpoint of pattern formability (soluble developability and thinning) and thermocompression bondability, are diamines containing fluoroalkyl groups, represented by the following formulas (19), (20), (21) and (22).

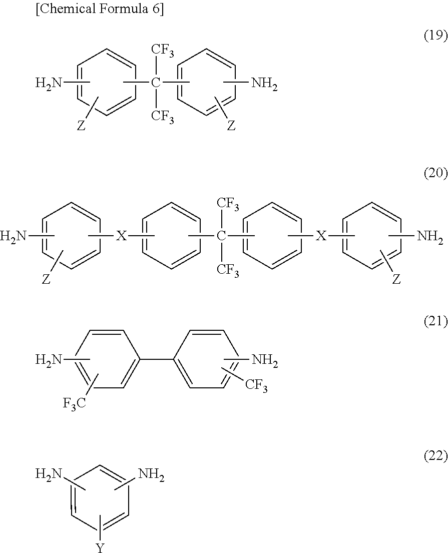

In the formulas, each X independently represents a single bond, —O—, —S—, —SO₂—, —CO—, —CH₂—, —C(CH₃)₂—, —CF₂— or —C(CF₃)₂—, Y represents a C1-30 organic group containing a fluoroalkyl group, and each Z independently represents an organic group containing —H or a C1-10 alkyl, carboxyl, phenolic hydroxyl, sulfo, thiol or fluoroalkyl group.

The imide group-containing resin preferably has an alkali-soluble group, from the viewpoint of pattern formability. An alkali-soluble group is a carboxyl group, phenolic hydroxyl group or glycol group, and from the viewpoint of allowing sufficient pattern formability and high-temperature adhesion, it more preferably has a carboxyl and/or phenolic hydroxyl group on a side chain, with a phenolic hydroxyl group being most preferred.

There are no particular restrictions on the imide group-containing resin having a carboxyl group on a side chain, and for example, it can be obtained by reacting an acid dianhydride with the carboxyl group-containing diamine described below. The carboxyl group-containing diamine is preferably a carboxyl group-containing aromatic diamine represented by the following formula (4) or (5), for adjustment of the pattern formability, thermocompression bondability and reflow resistance.

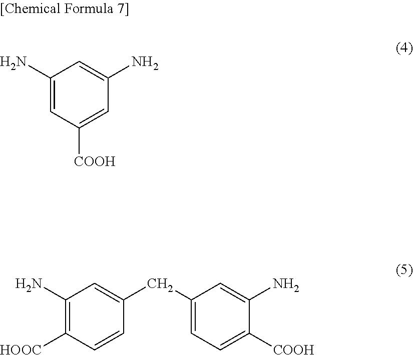

Phenolic hydroxyl-containing diamines to be used as starting materials for the imide group-containing resin are not particularly restricted when the tetracarboxylic dianhydride and diamine include a fluoroalkyl group, and examples include compounds such as 2,2′-bis(3-amino-4-hydroxyphenyl)hexafluoropropane, 3,3′-dihydroxy-4,4′-diaminobiphenyl, 3,3′-diamino-4,4′-dihydroxydiphenylsulfone, 2,2′ diaminobisphenol A, bis(2-hydroxy-3-amino-5-methylphenyl)methane, 2,6-di{(2-hydroxy-3-amino-5-methylphenyl)methyl}-4-methylphenol and propyl 2,6-di{(2-hydroxy-3-amino-5-methylphenyl)methyl}-4-hydroxybenzoate. These compounds may be used alone or in appropriate combinations of two or more.

Of these diamines, it is preferred to use fluoroalkyl group-containing diphenol diamines represented by formula (6) below, from the viewpoint of pattern formability (soluble developability and thinning), thermocompression bondability, high-temperature adhesion and reflow resistance. When such a diamine is used, the proportion is preferably no greater than 80 mol % and more preferably no greater than 60 mol % of the total diamine, from the viewpoint of attachment property, thermocompression bondability and high-temperature adhesion. Also, from the viewpoint of the film autosupporting property, high-temperature adhesion, reflow resistance and hermetic sealability, the proportion is preferably at least 5 mol %, more preferably at least 10 mol % and even more preferably at least 20 mol %. If the proportion is within this range it will be possible to adjust the Tg of the imide group-containing to the aforementioned range, and to impart an attachment property, thermocompression bondability, high-temperature adhesion, reflow resistance and hermetic sealability.

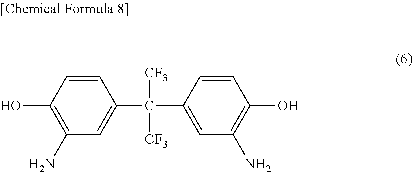

Soluble developability means that pattern formation occurs while the unexposed sections are dissolving in the developing solution.

From the viewpoint of imparting compatibility with other components, organic solvent solubility, alkali solubility, low-temperature attachment property and low-temperature thermocompression bondability, the diamine component is preferably an aliphatic etherdiamine represented by formula (8) below, and more preferably an ethyleneglycol- and/or propylene glycol-based diamine. Such an aliphatic etherdiamine, having a flexible skeleton exhibiting high hydrophilicity, can lower the Tg without impairing the alkali solubility. In formula (8), R¹, R² and R³ each independently represent a C1-10 alkylene group, and b represents an integer of 2-80.

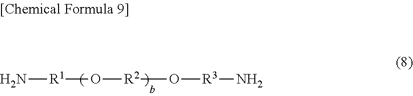

Specific aliphatic etherdiamines include aliphatic diamines, among which are polyoxyalkylenediamines such as JEFFAMINE D-230, D-400, D-2000, D-4000, ED-600, ED-900, ED-2000 and EDR-148 by San Techno Chemical Co., Ltd., and polyetheramine D-230, D-400 and D-2000 by BASF. These diamines constitute preferably 1-80 mol % and more preferably 5-60 mol % of the total diamines. If the amount is less than 1 mol % it will tend to be difficult to impart high-temperature adhesion and a hot flow property, while if it is greater than 80 mol % the Tg of the imide group-containing resin will be too low, tending to impair the autosupporting property of the film.

From the viewpoint of pattern formability, the aliphatic etherdiamine preferably has a propylene ether skeleton represented by formula (7) below, and a molecular weight of 300-600. When such a diamine is used, the proportion is preferably no greater than 80 mol % and more preferably no greater than 60 mol % of the total diamine, from the viewpoint of the film autosupporting property, high-temperature adhesion, reflow resistance and hermetic sealability. The proportion is also preferably 10 mol % or greater and more preferably 20 mol % or greater, from the viewpoint of attachment property, thermocompression bondability and high-temperature adhesion. If the proportion is within this range it will be possible to adjust the Tg of the imide group-containing to the aforementioned range, and to impart an attachment property, thermocompression bondability, high-temperature adhesion, reflow resistance and hermetic sealability.

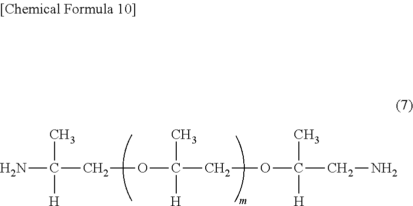

In the formula, m represents an integer of 3-7.

From the viewpoint of imparting tight adhesiveness and adhesion at room temperature, the diamine component is preferably a siloxanediamine represented by the following formula (9). In formula (9), R⁴ and R⁹ each independently represent a C1-5 alkylene or an optionally substituted phenylene group, R⁵, R⁶, R⁷ and R⁸ each independently represent a C1-5 alkyl, phenyl or phenoxy group, and d represents an integer of 1-5.

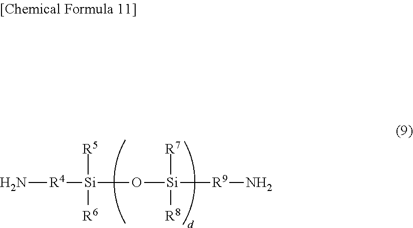

These diamines constitute preferably 5-50 mol % and more preferably 10-30 mol % of the total diamines. At below 5 mol %, the effect of adding the siloxanediamine will be reduced, and at greater than 50 mol % the compatibility with other components, the high-temperature adhesion and the developability will tend to be reduced.

These diamines may be used alone or in combinations of two or more.

As indicated above, the imide group-containing resin used for the invention is most preferably an imide group-containing resin comprising, as the diamine starting materials, a fluoroalkyl group-containing diphenol diamine represented by the structural formula shown above as a diamine in the starting material, at 20-60 mol % of the total diamines, an etherdiamine with a molecular weight of 300-600 at 20-60 mol % of the total diamines, and a siloxanediamine at 10-30 mol %, and having a Tg of 50-120° C.

The above-mentioned imide group-containing resin may be used alone, or if necessary it may be used as a mixture (blend) of two or more different types.

During synthesis of the imide group-containing resin, a monofunctional acid anhydride such as a compound represented by the following formula (10), (11) or (12), and/or a monofunctional amine such as a compound represented by the following formula (23), may be loaded into the condensation reaction solution to introduce a functional group other than the acid anhydride or diamine onto the polymer ends.

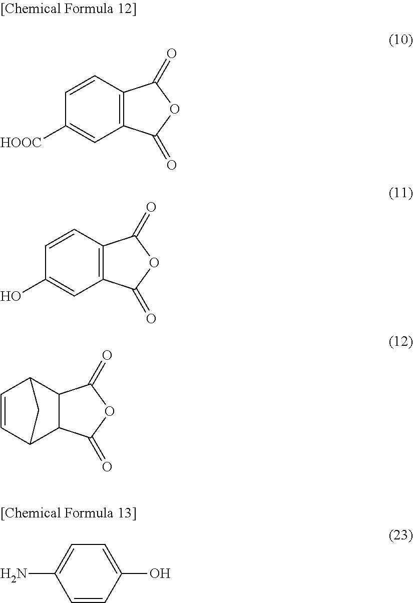

This can also lower the molecular weight of the polymer and improve the developability and thermocompression bondability during pattern formation. There are no particular restrictions on functional groups other than acid anhydrides or diamines, but from the viewpoint of improving the alkali solubility during pattern formation, alkali-soluble groups such as carboxyl, phenolic hydroxyl or glycol groups are preferred. From the viewpoint of imparting adhesion, it is preferred to use a compound having a radiation-polymerizable group and/or a thermosetting group, such as a compound represented by formula (12) above or an amino group-containing (meth)acrylate. From the viewpoint of imparting low hygroscopicity, it is preferred to use a compound with a siloxane skeleton or the like.

From the viewpoint of the photocuring property, the imide group-containing resin preferably has a transmittance of at least 10% and more preferably at least 20% for 365 nm light, when molded into a 30 μm film shape.

The content of component (A) in the photosensitive adhesive composition of this embodiment is preferably 5-90 mass %, more preferably 10-80 mass % and even more preferably 20-70 mass %, based on the total solid weight of the photosensitive adhesive composition. If the content is less than 5 mass % the developability during pattern formation will tend to be insufficient, while if it is greater than 90 mass % the developability and adhesion during pattern formation will tend to be insufficient.

When the alkaline solubility of component (A) is poor, or component (A) does not dissolve in alkalis, a resin with a carboxyl and/or hydroxyl group and/or a resin with a hydrophilic group may be added as a solubilizing aid. A resin with a hydrophilic group may be any alkali-soluble resin without any particular restrictions, and it may be a resin with a glycol group, such as an ethylene glycol or propyleneglycol group.

The photosensitive adhesive composition of this embodiment may also contain (D1) an epoxy resin, (D2) a compound with an ethylenic unsaturated group and an epoxy group or (D3) a phenol compound as the (D) curing component, with a curing accelerator or the like.

The (D1) epoxy resin preferably contains at least 2 epoxy groups in the molecule, from the viewpoint of high-temperature adhesion and reflow resistance, while from the viewpoint of pattern formability and thermocompression bondability it is more preferably a glycidyl ether-type epoxy resin which is liquid or semi-solid at room temperature (25° C.), and specifically having a softening temperature of no higher than 50° C. There are no particular restrictions on such resins, and examples thereof include bisphenol A-type (or AD-type, S-type and F-type) glycidyl ethers, hydrogenated bisphenol A-type glycidyl ethers, ethylene oxide-added bisphenol A-type glycidyl ethers, propylene oxide-added bisphenol A-type glycidyl ethers, trifunctional (or tetrafunctional) glycidyl ethers, glycidyl esters of dimer acids, and trifunctional (or tetrafunctional) glycidylamines. These may be used alone or in combinations of two or more.

From the viewpoint of the low outgas property, high-temperature adhesion and reflow resistance, the epoxy resin preferably has a 5% mass reduction temperature of 150° C. or higher, more preferably 180° C. or higher, even more preferably 200° C. or higher and most preferably 260° C. or higher.

The aforementioned 5% mass reduction temperature (hereunder reference to as “5% mass reduction temperature”) is the 5% mass reduction temperature as measured for the sample using a Simultaneous Thermogravimetric Differential Thermal Analyzer (TG/DTA6300 by SII NanoTechnology Inc.) with a temperature-elevating rate of 10° C./min and under a nitrogen flow (400 ml/min).

It is preferred to use an epoxy resin represented by the following formula (24) or (25) as the epoxy resin, from the viewpoint of imparting adequacy in terms of the 5% mass reduction temperature, pattern formability, high-temperature adhesion, reflow resistance and hermetic sealability.

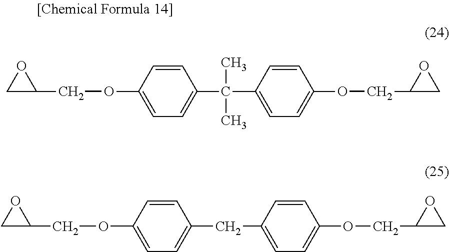

From the viewpoint of preventing electromigration and corrosion of metal conductor circuits, the epoxy resin used is preferably a high-purity product with a content of no greater than 300 ppm for impurity ions such as alkali metal ions, alkaline earth metal ions and halide ions, and particularly chloride ion or hydrolyzable chlorine.

The epoxy resin content is preferably 1-100 parts by mass and more preferably 5-50 parts by mass, with respect to 100 parts by mass of component (A). A content of greater than 100 parts by mass will tend to reduce the solubility in the aqueous alkali solution, the manageability, and the pattern formability. On the other hand, a content of less than 5 parts by mass will tend to prevent sufficient thermocompression bondability and high-temperature adhesion.

According to the invention, (D2) a compound with an ethylenic unsaturated group and an epoxy group may be further added from the viewpoint of thermocompression bondability, high-temperature adhesion and reflow resistance.

The ethylenic unsaturated group in component (D2) (a compound with an ethylenic unsaturated group and an epoxy group) may be a vinyl, allyl, propargyl, butenyl, ethynyl, phenylethynyl, maleimide, nadimide or (meth)acrylic group, and is preferably a (meth)acrylic group from the viewpoint of reactivity.

Component (D2) is not particularly restricted, and it may be glycidyl methacrylate, glycidyl acrylate, 4-hydroxybutyl acrylate glycidyl ether or 4-hydroxybutyl methacrylate glycidyl ether, or a compound obtained by reacting a compound with a functional group that reacts with epoxy groups and an ethylenic unsaturated group, with a polyfunctional epoxy resin. There are no particular restrictions on the functional groups that react with epoxy groups, and they include isocyanate, carboxyl, phenolic hydroxyl, hydroxyl, acid anhydride, amino, thiol and amide groups. These compounds may be used alone or in combinations of two or more different ones.

Component (D2) may be obtained, for example, by reacting a polyfunctional epoxy resin having at least 2 epoxy groups in the molecule with (meth)acrylic acid at 0.1-0.9 equivalents with respect to 1 epoxy group equivalent, in the presence of triphenylphosphine or tetrabutylammonium bromide.

From the viewpoint of storage stability, adhesion, low outgas property of the package during assembly heating and after assembly, high-temperature adhesion, reflow resistance and hermetic sealability, component (D2) has a 5% mass reduction temperature of preferably 150° C. or higher, more preferably 180° C. or higher, even more preferably 200° C. or higher and most preferably 260° C. or higher.

From the viewpoint of preventing electromigration and corrosion of metal conductor circuits, component (D2) is preferably a high-purity product with a content of no greater than 1000 ppm and more preferably no greater than 300 ppm, for impurity ions such as alkali metal ions, alkaline earth metal ions and halide ions, and particularly chloride ion or hydrolyzable chlorine. For example, the impurity ion concentration specified above can be satisfied by using a polyfunctional epoxy resin with a reduced content of alkali metal ions, alkaline earth metal ions and halide ions as the starting material.

For component (D2) satisfying the heat resistance and purity specified above, there are no particular restrictions but the starting materials may be bisphenol A-type (or AD-type, S-type or F-type) glycidyl ethers, hydrogenated bisphenol A-type glycidyl ethers, ethylene oxide-added bisphenol A and/or F-type glycidyl ethers, propylene oxide-added bisphenol A and/or F-type glycidyl ethers, phenol-novolac resin glycidyl ethers, cresol-novolac resin glycidyl ethers, bisphenol A-novolac resin glycidyl ethers, naphthalene resin glycidyl ethers, trifunctional (or tetrafunctional) glycidyl ethers, glycidyl ethers of dicyclopentadienephenol resins, glycidyl esters of dimer acids, trifunctional (or tetrafunctional) glycidylamines, naphthalene resin glycidylamines, and the like.

Particularly for improved thermocompression bondability, low-stress property and adhesion, and to maintain developability during pattern formation, the number of epoxy and ethylenic unsaturated groups of component (D2) is preferably no greater than 3 each, and in particular the number of ethylenic unsaturated groups is preferably no greater than 2. There are no particular restrictions on component (D2), but it is preferred to use a compound represented by the following formula (13), (14), (15), (16) or (17). In formulas (13)-(17), R¹² and R¹⁶ represent hydrogen or methyl groups, R¹⁰, R¹¹, R¹³ and R¹⁴ represent divalent organic groups, and R¹⁵-R¹⁸ represent organic groups with epoxy or ethylenic unsaturated groups.

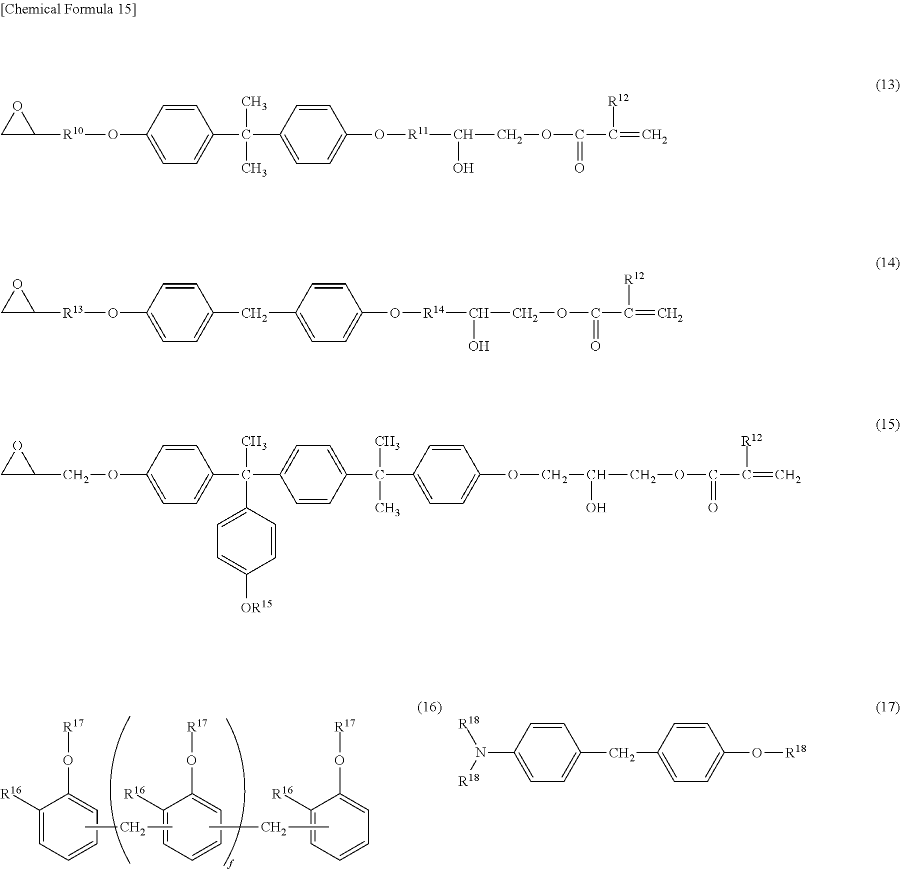

The content of component (D2) in the photosensitive adhesive composition of this embodiment is preferably 5-100 parts by mass and more preferably 10-70 parts by mass, with respect to 100 parts by mass of component (A). If the content exceeds 100 parts by mass, the thixotropic property will tend to be reduced during film formation, making it difficult to form a film, or the tack may increase, resulting in poor manageability. In addition, the resin composition will tend to lack solubility resulting in reduced developability during pattern formation, and the melt viscosity after photocuring will tend to be too low, resulting in deformation of the pattern during thermocompression bonding. On the other hand, if the content of component (D2) is less than 5 parts by mass, the thermocompression bondability, high-temperature adhesion and reflow resistance will tend to be reduced.

Preferred as the (D3) phenol compound, from the viewpoint of pattern formability, high-temperature adhesion and reflow resistance, are phenol-based compounds having at least 2 phenolic hydroxyl groups in the molecule. Example of such compounds include phenol-novolac, cresol-novolac, t-butylphenol-novolac, dicyclopentadienecresol-novolac, dicyclopentadienephenol-novolac, xylylene-modified phenol-novolac, naphthol-based compounds, trisphenol-based compounds, tetrakisphenol-novolac, bisphenol A-novolac, poly-p-vinylphenol and phenolaralkyl resins. Compounds with number-average molecular weights in the range of 400-4000 are preferred among these. This will help minimize outgas during heating, which can cause contamination of the semiconductor element or apparatus during the heating for semiconductor device assembly. The content of the (D3) phenol compound is preferably 1-100 parts by mass, more preferably 2-50 parts by mass and even more preferably 2-30 parts by mass with respect to 100 parts by mass of component (A). If the content exceeds 100 parts by mass, reactivity between the reactive compound with an ethylenic unsaturated group and an epoxy group and the radiation-polymerizable compound during exposure will be inadequate, or the hydrophilicity of the resin may increase, tending to reduce the film thickness or cause swelling after development. Also, penetration of the developing solution into the resin pattern will tend to increase, resulting in more outgas in the subsequent heat curing or in the thermal history of assembly, and significantly lowering the heat-resistant reliability or moisture-proof reliability. On the other hand, a content of less than 1 part by mass will tend to prevent high-temperature adhesion.

The increased pattern formability by addition of the (D3) phenol compound is believed to occur for the following reason. The photosensitive adhesive composition, containing (D3), is present as a low-molecular-weight alkali-soluble monomer during development. When a dissolution accelerator is thus contained in the composition, the solubility is partially increased, thus aiding penetration of the developing solution. Also, when a carboxyl group-containing resin is used as the dissolution accelerator, heat drying during film formation promotes reaction with the epoxy resin, tending to lower the pattern formability.

The improved high-temperature adhesion by addition of (D3) is attributed to the following reason. The photosensitive adhesive composition, containing (D3), is present as a low-molecular-weight thermosetting monomer during thermosetting. Having a low-molecular-weight curing agent thus contained in the composition aids molecular motion while hot, and promotes curing.

The phenol compound is preferably a phenol compound represented by the following formula (26), from the viewpoint of obtaining a high 5% mass reduction temperature and imparting sufficient pattern formability. By using a low-molecular-weight phenol compound represented by formula (26), it is possible to achieve both satisfactory pattern formability and high-temperature adhesion.

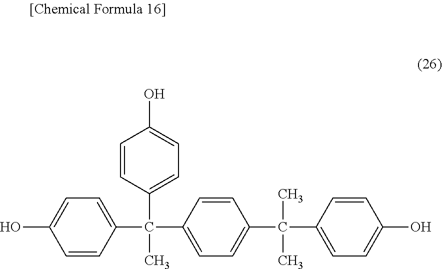

From the viewpoint of allowing sufficient pattern formability and thermocompression bondability to be imparted, the total amount of component (D) is preferably 10-150 parts by mass, more preferably 20-120 parts by mass and even more preferably 30-100 parts by mass, with respect to 100 parts by mass of component (A). Pattern formability can be adequately imparted within these ranges. Sufficient thermocompression bondability can also be imparted if the amount of low-molecular-weight component remaining after photoirradiation during pattern formation is increased.

Thermocompression bondability can thus be imparted by lowering the melt viscosity after photoirradiation. Specifically, the minimum melt viscosity between 20° C. and 200° C. after photoirradiation is preferably no higher than 30,000 Pa·s, more preferably no higher than 20,000 Pa·s and even more preferably no higher than 10,000 Pa·s. The lower limit is preferably at least 100 Pa·s and more preferably at least 1000 Pa·s, in order to inhibit pattern deformation during thermocompression bonding.

The minimum melt viscosity is the minimum value of the melt viscosity between 50° C. and 200° C., upon measurement of a sample that has been subjected to irradiation with a light quantity of 1000 mJ/cm² followed by development, washing and heat drying at 120° C. for 10 minutes, using an ARES viscoelasticity measuring apparatus (product of Rheometrix Scientific F.E.). The measuring plate was a parallel plate with a diameter of 8 mm, and the measuring conditions were set to a temperature increase of 5° C./min, a measuring temperature of 20-200° C. and a frequency of 1 Hz.

If the minimum melt viscosity is within this range, it will be possible to avoid pattern deformation and voids and impart sufficient thermocompression bondability.

The curing accelerator is not particularly restricted so long as it includes a curing accelerator that promotes epoxy curing/polymerization by heating, and examples thereof include imidazoles, dicyandiamide derivatives, dicarboxylic acid dihydrazides, triphenylphosphine, tetraphenylphosphonium tetraphenylborate, 2-ethyl-4-methylimidazole-tetraphenylborate and 1,8-diazabicyclo[5.4.0]undecene-7-tetraphenylborate. The content of the curing accelerator in the photosensitive adhesive composition is preferably 0.01-50 parts by mass with respect to 100 parts by mass of the epoxy resin.

The photosensitive adhesive composition can impart excellent high-temperature adhesion, reflow resistance and hermetic sealability by thermocompression bonding onto another member after pattern formation, followed by thermosetting at the prescribed temperature. The temperature for thermosetting is preferably between 100° C. and 220° C., more preferably between 120° C. and 200° C. and even more preferably between 150° C. and 180° C. A curing temperature of 220° C. or higher will tend to result in considerable thermal damage to surrounding materials, generation of thermal stress and fragility and reduced high-temperature adhesion of the adhesive resin composition, while a temperature of 100° C. or below will tend to result in lower high-temperature adhesion and a longer curing time, as the curing reaction of the thermosetting component fails to adequately proceed.

The (B) radiation-polymerizable compound may be a compound with an ethylenic unsaturated group, ethylenic unsaturated groups including vinyl, allyl, propargyl, butenyl, ethynyl, phenylethynyl, maleimide, nadimide and (meth)acrylic groups, with (meth)acrylic groups being preferred from the viewpoint of reactivity, and the radiation-polymerizable compound is preferably a bifunctional or greater (meth)acrylate. Such acrylates are not particularly restricted, and include diethyleneglycol diacrylate, triethyleneglycol diacrylate, tetraethyleneglycol diacrylate, diethyleneglycol dimethacrylate, triethyleneglycol dimethacrylate, tetraethyleneglycol dimethacrylate, trimethylolpropane diacrylate, trimethylolpropane triacrylate, trimethylolpropane dimethacrylate, trimethylolpropane trimethacrylate, 1,4-butanediol diacrylate, 1,6-hexanediol diacrylate, 1,4-butanediol dimethacrylate, 1,6-hexanediol dimethacrylate, pentaerythritol triacrylate, pentaerythritol tetraacrylate, pentaerythritol trimethacrylate, pentaerythritol tetramethacrylate, dipentaerythritol hexaacrylate, dipentaerythritol hexamethacrylate, styrene, divinylbenzene, 4-vinyltoluene, 4-vinylpyridine, N-vinylpyrrolidone, 2-hydroxyethyl acrylate, 2-hydroxyethyl methacrylate, 1,3-acryloyloxy-2-hydroxypropane, 1,2-methacryloyloxy-2-hydroxypropane, methylenebisacrylamide, N,N-dimethylacrylamide, N-methylolacrylamide, tris(β-hydroxyethyl)isocyanurate triacrylate, compounds represented by the following formula (18), urethane acrylate or urethane methacrylate, and urea acrylate.

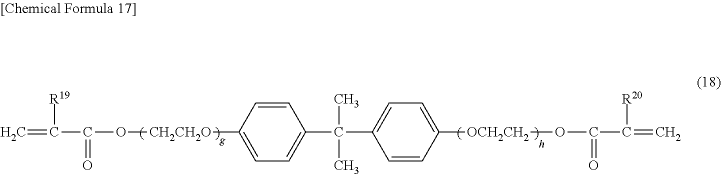

In formula (18), R¹⁹ and R²⁰ each independently represent hydrogen or a methyl group, and g and h each independently represent an integer of 1-20.

These radiation-polymerizable compounds may be used alone or in combinations of two or more. Among them, radiation-polymerizable compounds with a glycol skeleton, represented by formula (18) above, are preferred from the standpoint of imparting sufficient alkali solubility and solvent resistance after curing, and urethane acrylates and methacrylates and isocyanuric acid-containing acrylates and methacrylates are preferred from the standpoint of imparting sufficient high adhesion after curing.

The photosensitive adhesive composition of the invention also preferably contains a trifunctional or greater acrylate compound as the (B) radiation-polymerizable compound. This can further improve the adhesion after curing and inhibit outgas during heating.

The photosensitive adhesive composition of the invention also preferably contains as the (B) radiation-polymerizable compound, an isocyanuric acid ethylene oxide-modified diacrylate represented by the following formula (27) and/or an isocyanuric acid ethylene oxide-modified triacrylate represented by the following formula (28), from the viewpoint of allowing sufficient pattern formability, heat resistance and hermetic sealability to be imparted.

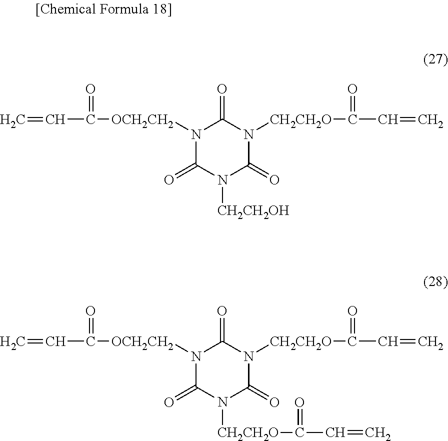

By using such a radiation-polymerizable compound with a high functional group equivalent, it is possible to improve the thermocompression bondability, and achieve low stress and low warping. The radiation-polymerizable compound with a high functional group equivalent preferably has at least 200 eq/g, more preferably at least 300 eq/g and even more preferably at least 400 eq/g of polymerizable functional groups. By using a radiation-polymerizable compound with at least 200 eq/g polymerizable functional group equivalents of a glycol skeleton or a urethane and/or isocyanuric group, it is possible to increase the developability and adhesion of the photosensitive adhesive composition, and to achieve low stress and low warping. A radiation-polymerizable compound with at least 200 eq/g polymerizable functional group equivalents and a radiation-polymerizable compound with no greater than 200 eq/g polymerizable functional group equivalents may also be used in combination. In this case, it is preferred to use a radiation-polymerizable compound having a urethane and/or isocyanuric group as a radiation-polymerizable compound.

The content of the (B) radiation-polymerizable compound is preferably 10-300 parts by mass, more preferably 20-250 parts by mass and even more preferably 40-100 parts by mass with respect to 100 parts by mass of component (A). A content of greater than 300 parts by mass will tend to lower the flow property during heat-fusion due to polymerization, thus reducing the adhesion during thermocompression bonding. A content of less than 10 parts by mass, on the other hand, will tend to result in lower solvent resistance after the photocuring by exposure, thus interfering with formation of the pattern, or in other words, increased film thickness variation and/or greater residue before and after development. It will also tend to result in melting during thermocompression bonding and deformation of the pattern.

Component (C) (the photoinitiator) is not particularly limited, but from the viewpoint of improving sensitivity, the molecular absorption coefficient for light with a wavelength of 365 nm is preferably at least 1000 ml/g·cm and more preferably at least 2000 ml/g·cm. The molecular absorption coefficient can be determined by preparing a 0.001 mass % acetonitrile solution of the sample and measuring the absorbance of the solution using a spectrophotometer (“U-3310” (trade name) by Hitachi High-Technologies Corp.).

When the photosensitive adhesive composition is formed into an adhesive layer with a film thickness of 30 μm or greater, the component (C) is more preferably subjected to bleaching with photoirradiation, from the viewpoint of improving sensitivity and increasing the interior curability. Examples for component (C) include compounds that undergo photo-discoloration under UV irradiation, among aromatic ketones such as 2-benzyl-2-dimethylamino-1-(4-morpholinophenyl)-butanone-1,2,2-dimethoxy-1,2-diphenylethan-1-one, 1-hydroxy-cyclohexyl-phenyl-ketone, 2-methyl-1-(4-(methylthio)phenyl)-2-morpholinopropanone-1,2,4-diethylthioxanthone, 2-ethylanthraquinone and phenanthrenequinone, benzyl derivatives such as benzyldimethylketal, 2,4,5-triarylimidazole dimers such as 2-(o-chlorophenyl)-4,5-diphenylimidazole dimer, 2-(o-chlorophenyl)-4,5-di(m-methoxyphenyl)imidazole dimer, 2-(o-fluorophenyl)-4,5-phenylimidazole dimer, 2-(o-methoxyphenyl)-4,5-diphenylimidazole dimer, 2-(p-methoxyphenyl)-4,5-diphenylimidazole dimer, 2,4-di(p-methoxyphenyl)-5-phenylimidazole dimer and 2-(2,4-dimethoxyphenyl)-4,5-diphenylimidazole dimer, acridine derivatives such as 9-phenylacridine and 1,7-bis(9,9′-acridinyl)heptane, and bisacylphosphine oxides such as bis(2,6-dimethoxybenzoyl)-2,4,4-trimethyl-pentylphosphine oxide and bis(2,4,6,-trimethylbenzoyl)-phenylphosphine oxide. These may be used alone or in combinations of two or more.

Component (C) may also comprise a photoinitiator that exhibits a function of promoting polymerization and/or addition reaction of an epoxy resin by exposure to radiation. Examples of such photoinitiators include photobase generators that generate bases by irradiation, and photoacid generators that generate acids by irradiation, with photobase generators being particularly preferred.

By using a photobase generator it is possible to further improve the high-temperature adhesion onto adherends and the humidity resistance of the photosensitive adhesive composition. The reason for this may be that the base generated from the photobase generator acts efficiently as a curing catalyst for the thermosetting resin, such as an epoxy resin, thus further increasing the crosslink density, and that the produced curing catalyst causes less corrosion of boards and the like. By including a photobase generator in the photosensitive adhesive composition, it is possible to improve the crosslink density and further reduce the outgas during standing at high temperature. The curing process presumably can also be accomplished at a lower temperature and in a shorter time.

Also, if component (A) has a high carboxyl and/or hydroxyl content ratio, there is a risk of increasing the post-curing moisture absorption coefficient and lowering the adhesive force after moisture absorption. With a photosensitive adhesive composition comprising a photobase generator, however, generation of a base by exposure to radiation can reduce the carboxyl and/or hydroxyl groups that remain after reaction of the carboxyl and/or hydroxyl groups with the epoxy resin, and thus result in higher levels of reflow resistance, as well as both adhesion and pattern formability.

Any photobase generator that is a compound that generates bases upon irradiation may be used, without any particular restrictions. Strongly basic compounds are preferred as bases to be generated, from the viewpoint of reactivity and curing speed. The pKa value, which is the logarithm of the acid dissociation constant, is generally used as the index of the basicity, and the pKa value is preferably 7 or greater and more preferably 9 or greater in aqueous solution.

There may also be used as photobase generators, oxime derivatives that generate primary amino groups by irradiation of active light rays, or commercially available photoradical generators such as 2-methyl-1-(4-(methylthio)phenyl)-2-morpholinopropan-1-one (IRGACURE 907 by Ciba Specialty Chemicals, Inc.), 2-benzyl-2-dimethylamino-1-(4-morpholinophenyl)-butanone-1 (IRGACURE 369 by Ciba Specialty Chemicals, Inc.), 2-dimethylamino-2-([4-methylphenyl)methyl]-1-[4-(4-morpholinyl)phenyl-1-butanone (IRGACURE 379EG by Ciba Specialty Chemicals, Inc.) and 3,6-bis-(2-methyl-2-morpholino-propionyl)-9-N-octylcarbazole (OPTOMER N-1414 by Adeka Corp.), and hexaarylbisimidazole derivatives (optionally having substituents such as halogens, alkoxy, nitro or cyano on the phenyl group), and benzoisooxazolone derivatives.

From the viewpoint of heat resistance, the (C) photoinitiator is preferably a compound with an oxime ester group represented by the following formula (29), and/or a compound with a morpholine ring represented by the following formula (30) or (31).

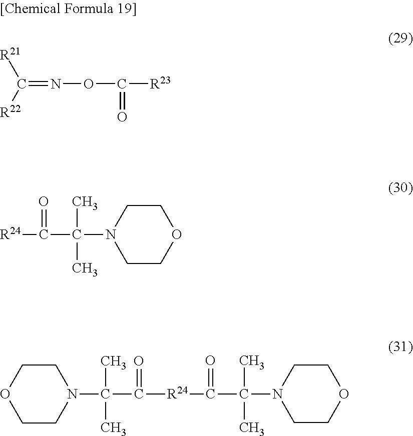

In these formulas, R²¹ and R²² each independently represent hydrogen, C1-7 alkyl or an organic group containing an aromatic hydrocarbon group, R²³ represents C1-7 alkyl or an organic group containing an aromatic hydrocarbon group, and R²⁴ represents an organic group containing an aromatic hydrocarbon group.

There are no particular restrictions on aromatic hydrocarbon groups, and as examples there may be mentioned phenyl, naphthyl, benzoin derivatives, carbazole derivatives, thioxanthone derivatives and benzophenone derivatives. The aromatic hydrocarbon group may also have substituents.

Particularly preferred for the (C) photoinitiator are oxime esters and/or compounds with morpholine rings, which are compounds having a molecular absorption coefficient of 1000 ml/g·cm or greater for light with a wavelength of 365 nm and having a 5% mass reduction temperature of 150° C. or higher.

Such photoinitiators include compounds represented by the following formulas (32), (33) and (34). By using such a photoinitiator it is possible to exhibit satisfactory sensitivity during pattern formation and inhibit film loss or concavoconvexities in the adhesive surface during development, thereby improving the height precision after thermocompression bonding. In addition, because of fewer concavoconvexities caused by development, the adhesive exhibits satisfactory thermocompression bondability and functions as a thermosetting catalyst as well, so that satisfactory adhesion after curing is exhibited. These may be used alone or in combinations of 2 or more, and especially preferred is a combination of a compound represented by the following formula (33) and a compound represented by the following formula (34). The compound represented by formula (33) is commercially available as “I-OXE02” (trade name of Ciba, Japan).

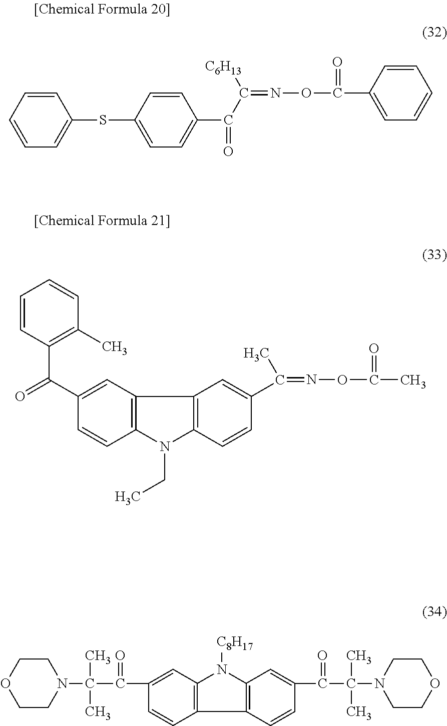

When the photosensitive adhesive composition of this embodiment contains a compound with an oxime ester and/or morpholine ring as a photoinitiator, the photosensitive adhesive composition may further contain a different photoinitiator. When the photosensitive adhesive composition is used as an adhesive layer with a film thickness of no greater than 30 μm, a compound with an oxime ester and/or morpholine ring may be added alone, or it may be used together with another photoinitiator if it is to be made into an adhesive layer with a film thickness of 50 μm or greater.

Examples of such other photoinitiators include compounds that undergo photo-discoloration under UV irradiation, among aromatic ketones such as 2-benzyl-2-dimethylamino-1-(4-morpholinophenyl)-butanone-1,2,2-dimethoxy-1,2-diphenylethan-1-one, 1-hydroxy-cyclohexyl-phenyl-ketone, 2-methyl-1-(4-(methylthio)phenyl)-2-morpholinopropanone-1,2,4-diethylthioxanthone, 2-ethylanthraquinone and phenanthrenequinone, benzyl derivatives such as benzyldimethylketal, 2,4,5-triarylimidazole dimers such as 2-(o-chlorophenyl)-4,5-diphenylimidazole dimer, 2-(o-chlorophenyl)-4,5-di(m-methoxyphenyl)imidazole dimer, 2-(o-fluorophenyl)-4,5-phenylimidazole dimer, 2-(o-methoxyphenyl)-4,5-diphenylimidazole dimer, 2-(p-methoxyphenyl)-4,5-diphenylimidazole dimer, 2,4-di(p-methoxyphenyl)-5-phenylimidazole dimer and 2-(2,4-dimethoxyphenyl)-4,5-diphenylimidazole dimer, acridine derivatives such as 9-phenylacridine and 1,7-bis(9,9′-acridinyl)heptane, and bisacylphosphine oxides such as bis(2,6-dimethoxybenzoyl)-2,4,4-trimethyl-pentylphosphine oxide and bis(2,4,6,-trimethylbenzoyl)-phenylphosphine oxide (trade name: “I-819” by Ciba, Japan). These may be used alone or in combinations of two or more. By using such photoinitiators that undergo photo-discoloration, it is possible to obtain an adhesive pattern having perpendicular pattern side walls with respect to the adherend.

It is preferred to use a compound represented by formula (32), or a compound represented by formula (33) and/or a compound represented by formula (34), together with the aforementioned photoinitiator that undergoes photo-discoloration. By using these in combination, it is possible to obtain a photosensitive adhesive simultaneously exhibiting pattern formability, thermocompression bondability and high-temperature adhesion.

The photosensitive adhesive composition of this embodiment may include (E) a peroxide as a thermal radical generator, if necessary. The (E) peroxide is preferably an organic peroxide. The organic peroxide preferably has a 1 minute half-life temperature of 120° C. or higher, and more preferably 150° C. or higher. The organic peroxide is selected in consideration of factors including the conditions for preparing the photosensitive adhesive composition, the film formation temperature, the curing (attachment) conditions, the other process conditions and the storage stability. There are no particular restrictions on peroxides that may be used, examples including 2,5-dimethyl-2,5-di(t-butylperoxyhexane), dicumyl peroxide, t-butylperoxy-2-ethyl hexanate, t-hexylperoxy-2-ethyl hexanate, 1,1-bis(t-butylperoxy)-3,3,5-trimethylcyclohexane, 1,1-bis(t-hexylperoxy)-3,3,5-trimethylcyclohexane and bis(4-t-butylcyclohexyl)peroxy dicarbonate, and any one of these may be used alone, or two or more may be used in combination.

The addition amount of the (E) peroxide is preferably 0.01-20 mass %, more preferably 0.1-10 mass % and most preferably 0.5-5 mass %, with respect to the total amount of the ethylenic unsaturated group-containing compound. If the amount is less than 0.01 mass % the curability will be reduced and the effect of addition weakened, while if it is greater than 5 mass % the amount of outgas will increase and the storage stability will be reduced.

The (E) peroxide is not particularly restricted so long as it is a compound with a half-life temperature of 120° C. or higher, and examples include PERHEXA 25B (product of NOF Corp.), 2,5-dimethyl-2,5-di(t-butylperoxyhexane) (1 minute half-life temperature: 180° C.), Percumyl D (product of NOF Corp.) and dicumyl peroxide (1 minute half-life temperature: 175° C.).

In order to impart storage stability, process adaptability or an antioxidant property to the photosensitive adhesive composition of this embodiment, there may also be added polymerization inhibitors or antioxidants such as quinones, polyhydric phenols, phenols, phosphites and sulfur compounds, within ranges that do not impair the curability.

An appropriate (F) filler may also be added to the photosensitive adhesive composition of the invention. Examples of fillers that may be used include metal fillers such as silver powder, gold dust, copper powder and nickel powder, inorganic fillers such as alumina, aluminum hydroxide, magnesium hydroxide, calcium carbonate, magnesium carbonate, calcium silicate, magnesium silicate, calcium oxide, magnesium oxide, aluminum oxide, aluminum nitride, crystalline silica, amorphous silica, boron nitride, titania, glass, iron oxide and ceramics, and organic fillers such as carbon and rubber-based fillers, without any particular restrictions on the type or form.

The filler may be selected for use according to the desired function. For example, a metal filler is added to impart electrical conductivity, thermal conductivity or a thixotropic property to the resin composition, a non-metal inorganic filler is added to impart thermal conductivity, a low thermal expansion property or low hygroscopicity to the adhesive layer, and an organic filler is added to impart toughness to the adhesive layer.

These metal fillers, inorganic fillers or organic fillers may be used alone or in combinations of two or more. Metal fillers, inorganic fillers and insulating fillers are preferred from the viewpoint of imparting electrical conductivity, thermal conductivity, a low moisture absorption property and an insulating property, which are required for semiconductor device adhesive materials, and among inorganic fillers and insulating fillers there are preferred silica fillers from the viewpoint of satisfactory dispersibility in resin varnishes and high adhesive force when hot.

The filler preferably has a mean particle size of no greater than 10 μm and a maximum particle size of no greater than 30 μm, and more preferably a mean particle size of no greater than 5 μm and a maximum particle size of no greater than 20 μm. If the mean particle size exceeds 10 μm and the maximum particle size exceeds 30 μm, it may not be possible to satisfactorily obtain an effect of improved fracture toughness. There are no particular restrictions on the lower limits for the mean particle size and maximum particle size, but normally both will be 0.001 μm.

The filler content may be determined according to the properties and function to be imparted, but it is preferably 0-50 mass %, more preferably 1-40 mass % and even more preferably 3-30 mass % with respect to the total of the resin component and filler. Increasing the amount of filler can result in low gelatinization, low moisture absorption and a high elastic modulus, and can effectively improve the dicing property (cuttability with a dicer blade), wire bonding property (ultrasonic efficiency) and hot bonding strength.

If the filler is increased above the necessary amount the thermocompression bondability and pattern formability will tend to be impaired, and therefore the filler content is preferably limited to within the range specified above. The optimal filler content is determined for the desired balance of properties. In cases where a filler is used, mixing and kneading may be accomplished using an appropriate combination of dispersers such as an ordinary stirrer, kneader, triple roll, ball mill or the like.

Various coupling agents may also be added to the photosensitive adhesive composition of this embodiment to improve the interfacial bonding between different types of materials. Examples of coupling agents include silane-based, titanium-based and aluminum-based agents, among which silane-based coupling agents are preferred for a greater effect, and compounds with thermosetting groups such as epoxy groups or radiation-polymerizable groups such as methacrylate and/or acrylate groups are more preferred. The boiling point and/or decomposition temperature of the silane-based coupling agent is preferably 150° C. or higher, more preferably 180° C. or higher and even more preferably 200° C. or higher. That is, it is most preferred to use a silane-based coupling agent with a boiling point and/or decomposition temperature of 200° C. or higher, and having thermosetting groups such as epoxy groups or radiation-polymerizable groups such as methacrylate and/or acrylate groups. The amount of coupling agent used is preferably 0.01-20 parts by mass with respect to 100 parts by mass of component (A) that is used, from the standpoint of the effect, heat resistance and cost.

An ion scavenger may also be added to the photosensitive adhesive composition of this embodiment to adsorb ionic impurities and improve the insulating reliability when wet. Such an ion scavenger is not particularly restricted, and as examples there may be mentioned compounds known as copper inhibitors to prevent ionization and dissolution of copper, such as triazinethiol compounds and phenol-based reducing agents, and inorganic compounds such as powdered bismuth-based, antimony-based, magnesium-based, aluminum-based, zirconium-based, calcium-based, titanium-based and tin-based compounds, as well as mixtures of the same. Specific examples include, but are not restricted to, inorganic ion scavengers by Toagosei Co., Ltd. under the trade names of IXE-300 (antimony-based), IXE-500 (bismuth-based), IXE-600 (antimony/bismuth mixture-based), IXE-700 (magnesium/aluminum mixture-based), IXE-800 (zirconium-based) and IXE-1100 (calcium-based). Any of these may be used alone or in mixtures of two or more. The amount of ion scavenger used is preferably 0.01-10 parts by mass with respect to 100 parts by mass of component (A), from the viewpoint of effect of the addition, heat resistance, and cost.

The photosensitive adhesive of this embodiment has a high-temperature adhesion of preferably 1 MPa or greater, more preferably 2 MPa or greater, even more preferably 3 MPa or greater and most preferably 5 MPa or greater. By imparting such high-temperature adhesion it is possible to sufficiently impart heat-resistant reliability, reflow resistance and hermetic sealability in steps of heating such as solder reflow.

The high-temperature adhesion is the adhesive force (maximum stress) measured for a stack comprising a 3 mm×3 nim×400 pin thick silicon chip and a 10 mm×10 mm×0.55 mm thick glass panel bonded via an adhesive layer made of a photosensitive adhesive composition, with a thickness of about 40 μm that has been subjected to an exposure step, developing step and heating step, under conditions with a measuring temperature of 260° C., a measuring speed of 50 μm/sec and a measuring height of 50 μm, and with external force applied to the side wall of the silicon chip in the shear direction. The measuring apparatus used was a “Dage-4000” adhesive force tester by Dage Corp.

The photosensitive adhesive preferably has a 110° C. storage elastic modulus of 10 MPa or greater, more preferably 15 MPa or greater and most preferably 20 MPa or greater. By imparting such an elastic modulus, it is possible to inhibit condensation during moisture absorption treatment at 110° C., and to provide a semiconductor device imparted with sufficient hermetic sealability.

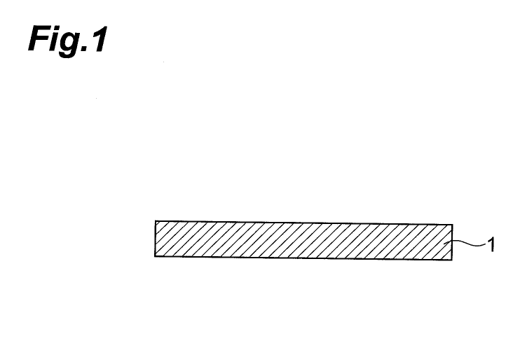

A film adhesive can be obtained by molding the photosensitive adhesive composition into a film. FIG. 1 is an end view showing an embodiment of a film adhesive of the invention. The film adhesive 1 shown in FIG. 1 is obtained by forming a film from the photosensitive adhesive composition.

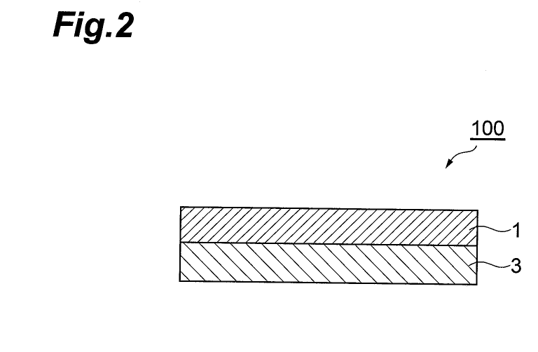

The film adhesive 1 is formed into a film by, for example, coating the photosensitive adhesive composition onto a base 3 as shown in FIG. 2, and drying it. It is thus possible to obtain an adhesive sheet 100 comprising a base 3 and an adhesive layer 1 composed of the film adhesive formed on the base 3. FIG. 2 is an end view showing an embodiment of an adhesive sheet 100 of the invention. The adhesive sheet 100 shown in FIG. 2 is constructed of a base 3, and an adhesive layer 1 composed of a film adhesive formed on one side of the base.

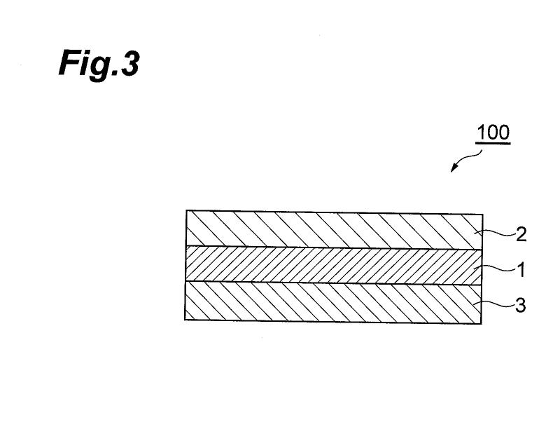

FIG. 3 is a schematic end view showing another embodiment of an adhesive sheet of the invention. The adhesive sheet 100 shown in FIG. 3 is constructed of a base 3, an adhesive layer 1 composed of a film adhesive, and a cover film 2, formed on one side of the base.

The film adhesive 1 may be obtained by combining component (A), component (B), component (C), component (D), and other components as necessary, in an organic solvent, kneading the mixture to prepare a varnish, coating the varnish onto the base 3 to form a varnish layer, drying the varnish layer by heating, and then removing the base 3. It may also be stored and used as an adhesive sheet 100 without removal of the base 3.

The organic solvent used to prepare the varnish, i.e. the varnish solvent, is not particularly restricted so long as it can uniformly dissolve or disperse the material. Examples include dimethylformamide, toluene, benzene, xylene, methyl ethyl ketone, tetrahydrofuran, ethylcellosolve, ethylcellosolve acetate, dioxane, cyclohexanone, ethyl acetate and N-methyl-pyrrolidinone.

The mixing and kneading can be accomplished by an appropriate combination of dispersers such as an ordinary stirrer, kneader, triple roll or ball mill. The drying by heat is accomplished at a temperature at which component (D) does not completely react, and under conditions for adequate volatilization of the solvent. The “temperature at which component (D) does not completely react” is, specifically, a temperature below the peak temperature for heat of reaction, with measurement using a DSC (for example, a “Model DSC-7” (trade name) by Perkin-Elmer), with a sample weight of 10 mg, a temperature-elevating rate of 5° C./min and a measuring atmosphere of air. Specifically, the varnish layer is dried by heating, usually at 60-180° C. for 0.1-90 minutes. The preferred thickness of the varnish layer before drying is 1-200 μm. A thickness of less than 1 μm will tend to result in an inadequate adhesive anchoring function, while a thickness of greater than 200 μm will tend to increase the residual volatile content described hereunder.

The preferred residual volatile content for the obtained varnish layer is no greater than 10 mass % and more preferably no greater than 3 mass %. A residual volatile content of greater than 10 mass % will tend to result in more residual voids in the interior of the adhesive layer due to expansion by volatilization of the solvent during the assembly heating, thus tending toward insufficient humidity resistance. It will also tend to increase the possibility of contamination of the surrounding material or parts by volatile components generated during heating. The conditions for measuring the residual volatilizing components were as follows. Specifically, the residual volatile content for a film adhesive 1 cut to a size of 50 mm×50 mm is the residual volatile content (%) obtained from the following formula, where M1 is the initial mass and M2 is the mass after heating the film adhesive 1 for 3 hours in an oven at 160° C.

Residual volatile content (%)=[(M2−M1)/M1]×100 Formula:

The base 3 is not particularly restricted so long as it can withstand the drying conditions. For example, a polyester film, polypropylene film, polyethylene terephthalate film, polyimide film, polyetherimide film, polyether naphthalate film or methylpentene film may be used as the base 3. A film used as the base 3 may also be a multilayer film comprising a combination of two or more different types, and the surface may be treated with a silicone-based or silica-based release agent.

The film adhesive 1 may be laminated with a dicing sheet to form an adhesive sheet. The dicing sheet is a sheet comprising a pressure-sensitive adhesive layer formed on a base, and the pressure-sensitive adhesive layer may be a pressure-sensitive type or radiation-curing type. The base is preferably an expandable base. Using such an adhesive sheet, it is possible to obtain an integrated dicing/die bond adhesive sheet having a function as a die bond film and also having a function as a dicing sheet.

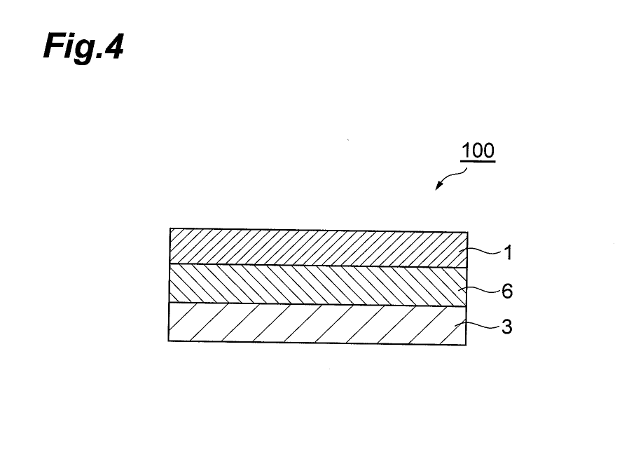

Specifically, the integrated dicing/die bond adhesive sheet may be an adhesive sheet 100 such as shown in FIG. 4, having a base 3, a pressure-sensitive adhesive layer 6 and a film adhesive (adhesive layer) 1 laminated in that order.

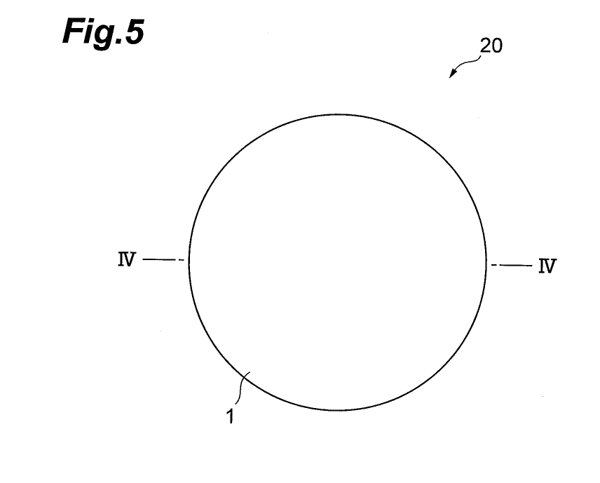

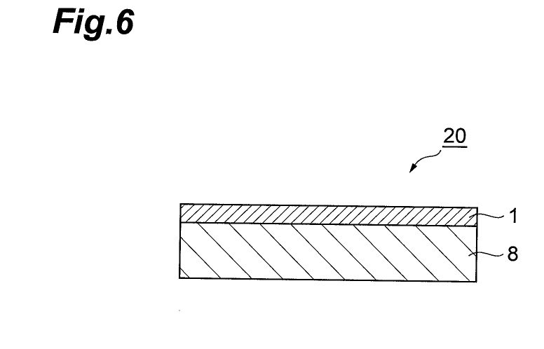

FIG. 5 is a top view showing an embodiment of a semiconductor wafer with an adhesive layer according to the invention, and FIG. 6 is an end view of FIG. 5 along line IV-IV. The semiconductor wafer with an adhesive layer 20 shown in FIGS. 5 and 6 comprises a semiconductor wafer 8, and a film adhesive (adhesive layer) 1 formed on one side thereof.

The semiconductor wafer with an adhesive layer 20 is obtained by laminating the film adhesive 1 on the semiconductor wafer 8 while heating. The film adhesive 1 can be attached to the semiconductor wafer 8 at a low temperature of, for example, between room temperature (25° C.) and about 150° C.

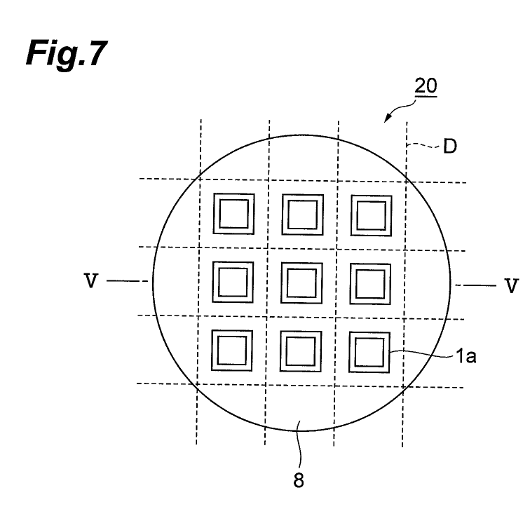

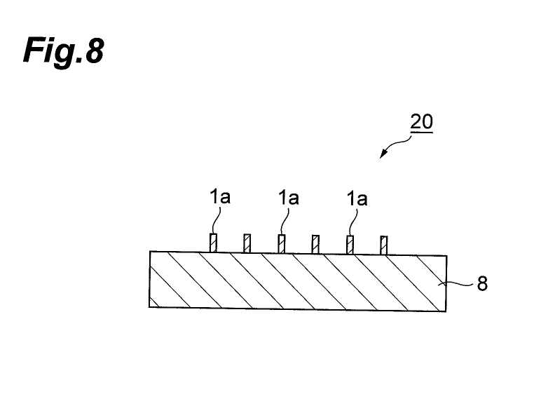

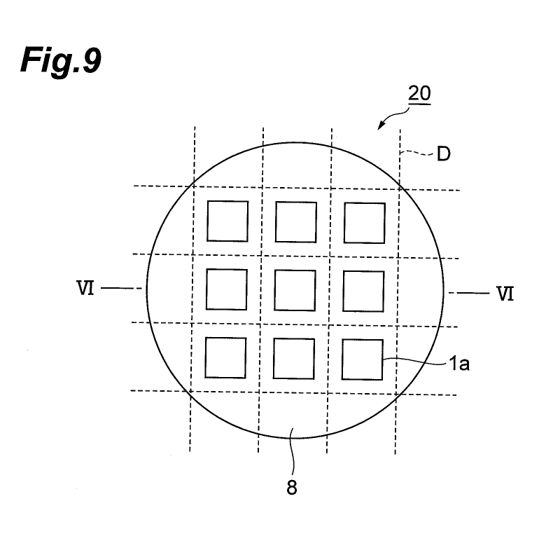

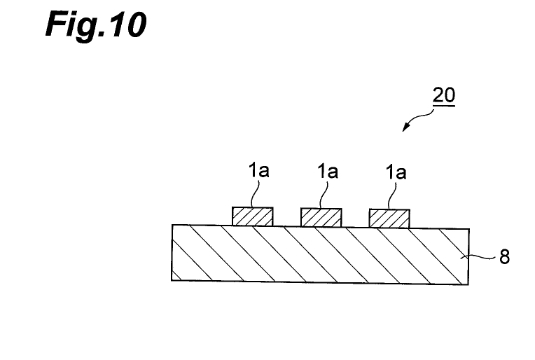

FIG. 7 and FIG. 9 are top views showing an embodiment of an adhesive pattern according to the invention, FIG. 8 is an end view of FIG. 7 along line V-V, and FIG. 10 is an end view of FIG. 9 along line VI-VI. The adhesive pattern 1a shown in FIGS. 7, 8, 9 and 10 is formed on the semiconductor wafer 8 as the adherend, so as to form patterns along roughly square sides, or square patterns.

The adhesive pattern 1a is formed by laminating the adhesive layer 1 on the semiconductor wafer 8 as the adherend to obtain a semiconductor wafer with an adhesive layer 20, exposing the adhesive layer 1 through a photomask, and developing the exposed adhesive layer 1 with an alkali developing solution. This yields a semiconductor wafer with an adhesive layer 20 on which an adhesive pattern 1a has been formed.

A semiconductor device produced using a film adhesive of the invention will now be explained in detail with reference to the accompanying drawings. Semiconductor devices with various structures have been proposed in recent years, and use of the film adhesive of the invention is not limited to semiconductor devices having the structures described below.

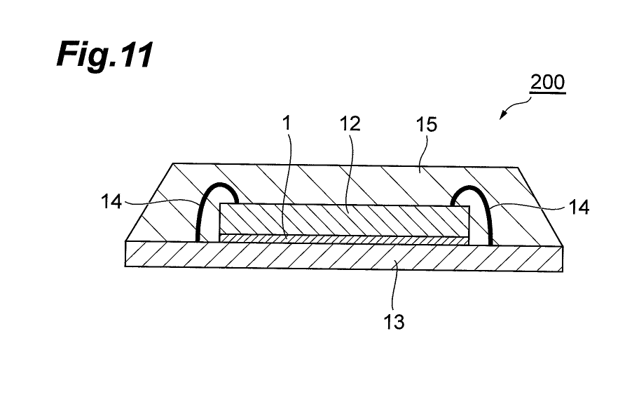

FIG. 11 is an end view showing an embodiment of a semiconductor device according to the invention. In the semiconductor device 200 shown in FIG. 11, the semiconductor element 12 is bonded to the semiconductor element-mounting supporting member 13 via a film adhesive 1, and the connecting terminals (not shown) of the semiconductor element 12 are electrically connected to external connecting terminals (not shown) via wires 14, and sealed with a sealing material 15.

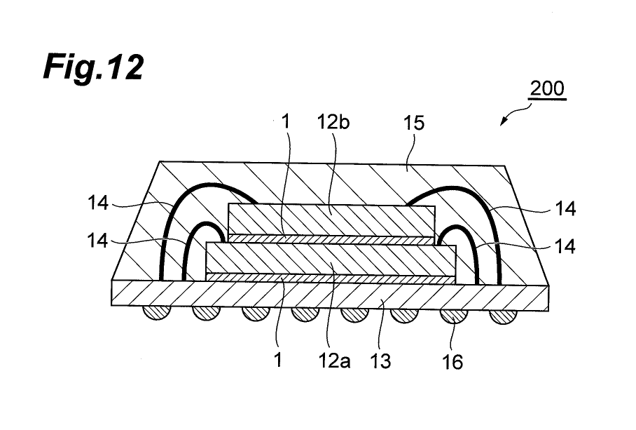

FIG. 12 is an end view showing another embodiment of a semiconductor device according to the invention. In the semiconductor device 200 shown in FIG. 12, a first-level semiconductor element 12a is bonded to the semiconductor element-mounting supporting member 13 on which terminals 16 have been formed, via a film adhesive 1, and a second-level semiconductor element 12b is bonded on the first-level semiconductor element 12a also via the film adhesive 1. The connecting terminals (not shown) of the first-level semiconductor element 12a and second-level semiconductor element 12b are electrically connected with external connecting terminals via wires 14, and are sealed with a sealing material. Thus, the film adhesive of the invention may be suitably used in a semiconductor device having a construction with a plurality of layered semiconductor elements.

The semiconductor devices (semiconductor packages) shown in FIG. 11 and FIG. 12 can be obtained, for example, by dicing the semiconductor wafer with an adhesive layer 20 shown in FIG. 9 along the dotted lines D, thermocompression bonding the diced adhesive layer-attached semiconductor element onto the semiconductor element-mounting supporting member 13 to bond them, and then passing it through a wire bonding step, and if necessary also a sealing step with a sealing material. The heating temperature for thermocompression bonding is normally 20-250° C., the load is normally 0.01-20 kgf and the heating time is normally 0.1-300 seconds.

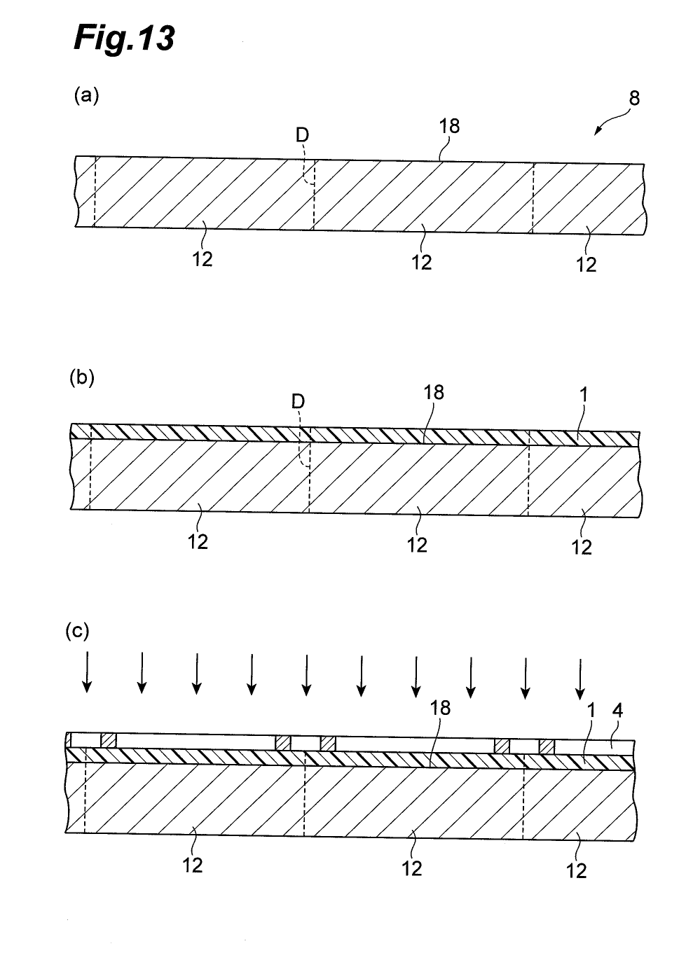

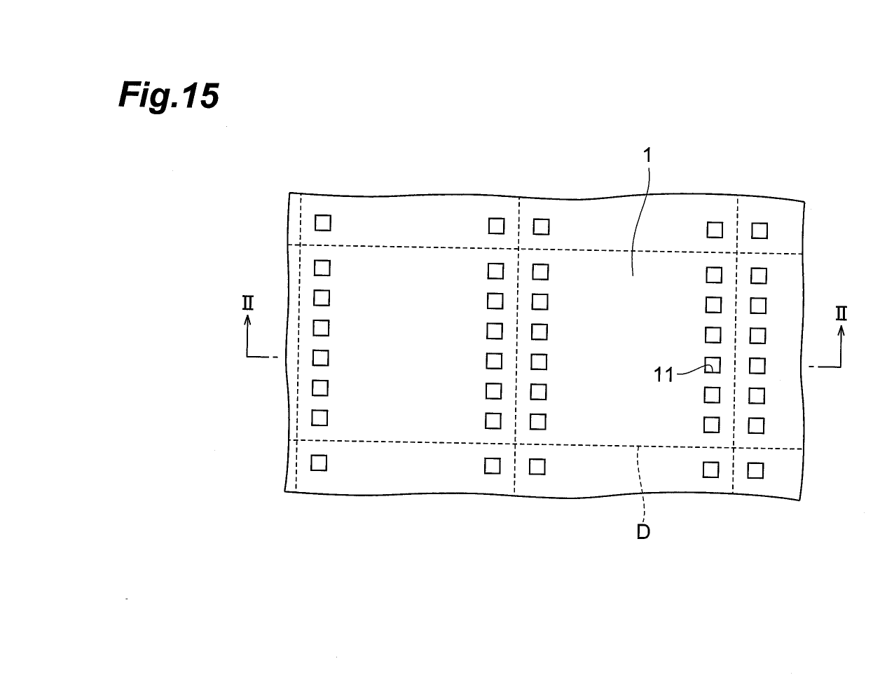

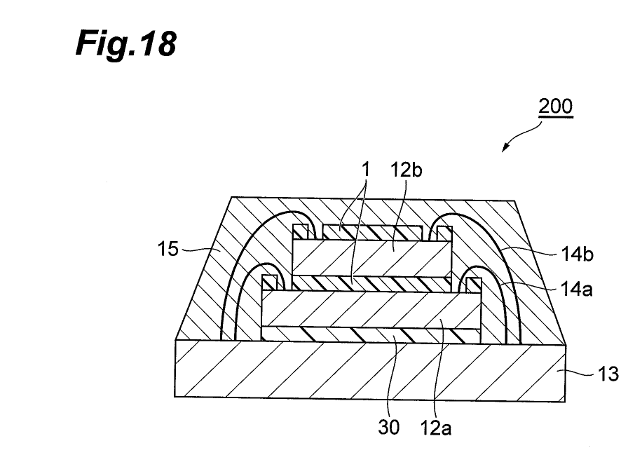

The rest of this embodiment of the semiconductor device of the invention is as shown in FIG. 18. A method for manufacturing the semiconductor device shown in FIG. 18 will now be explained in detail with reference to the accompanying drawings. FIGS. 13, 14 and 16-19 are end views showing embodiments of the method for manufacturing a semiconductor device of the invention, and FIG. 15 is a top view showing an embodiment of the method for manufacturing a semiconductor device of the invention.

The method for manufacturing a semiconductor device according to this embodiment comprises the following (step 1) to (step 7).

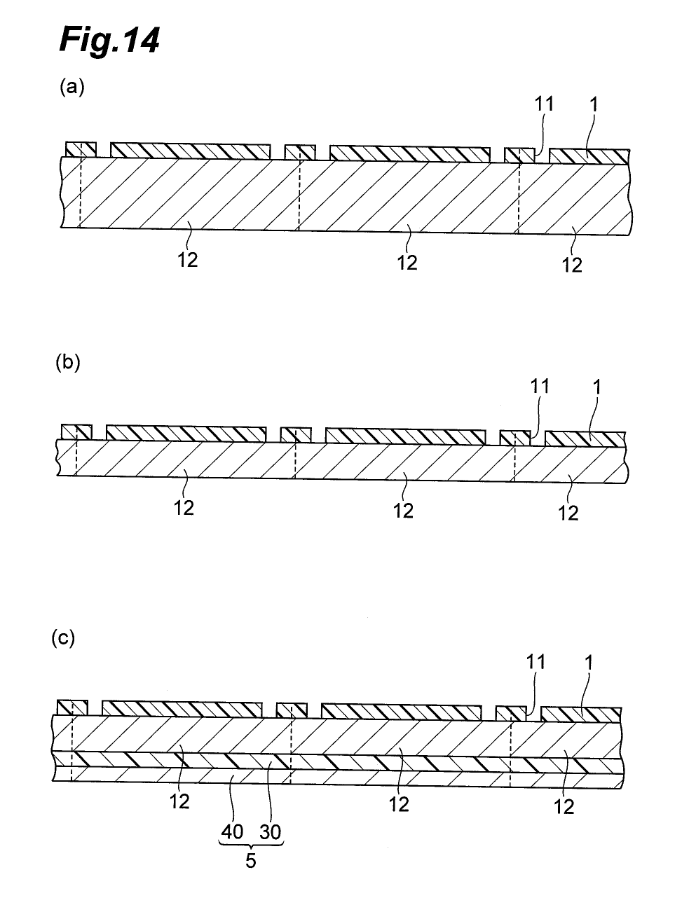

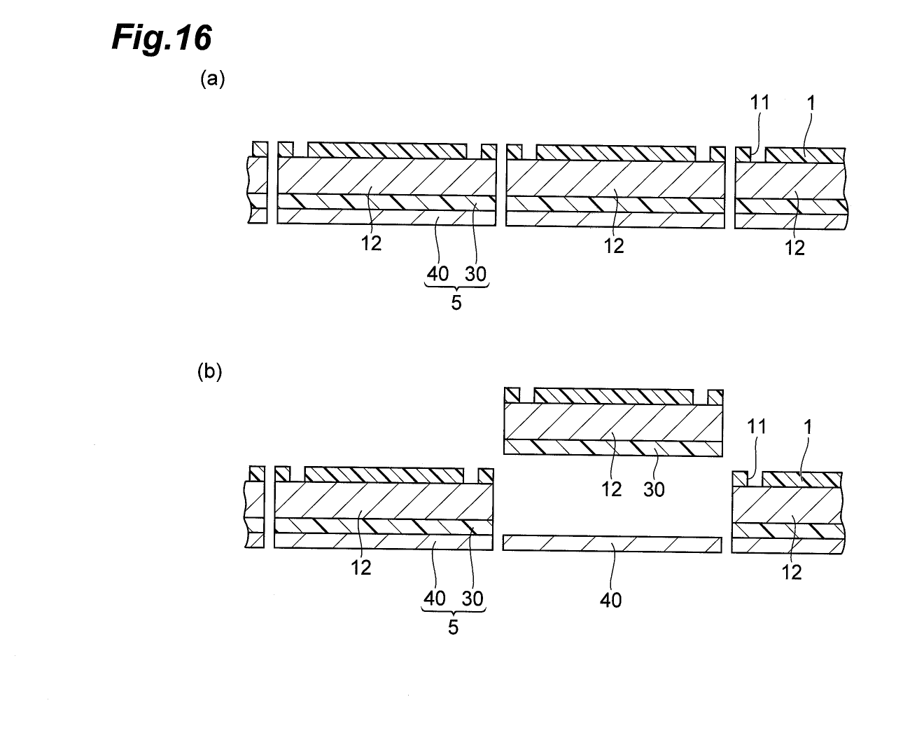

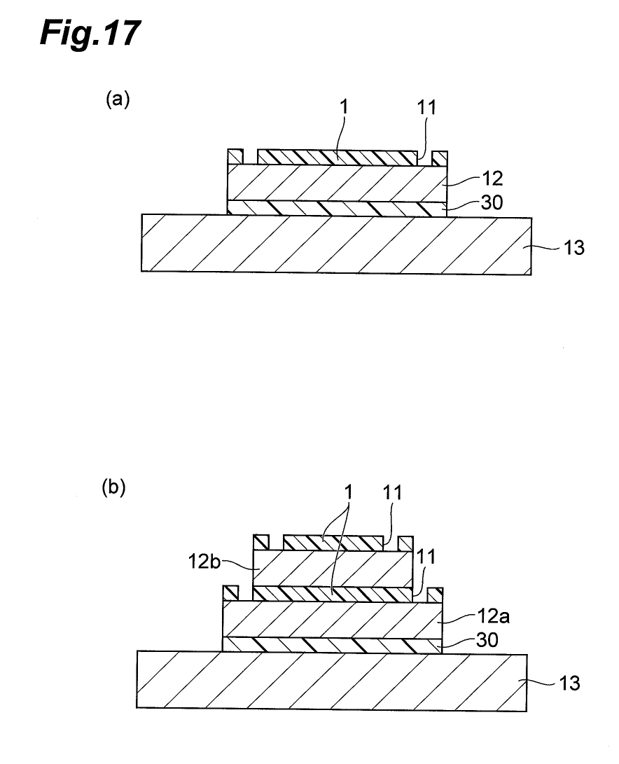

(Step 1) A step in which a film adhesive (adhesive layer) 1 is laminated on the circuit side 18 of a semiconductor chip (semiconductor element) 12 formed in a semiconductor wafer 8 (FIGS. 13(a) and (b)).
(Step 2) A step in which the adhesive layer 1 formed on the circuit side 18 of the semiconductor chip 12 is patterned by exposure and development (FIG. 13(c) and FIG. 14(a)).
(Step 3) A step in which the semiconductor wafer 8 is polished from the side opposite the circuit side 18, for thinning of the semiconductor wafer 8 (FIG. 14(b)).
(Step 4) A step in which the semiconductor wafer 8 is diced into semiconductor chips 12 by dicing (FIG. 14(c) and FIG. 16(a)).
(Step 5) A step in which the semiconductor chips 12 are picked up and mounted on a board-shaped supporting member for a semiconductor device (semiconductor element-mounting supporting member) 13 (FIG. 16(b) and FIG. 17(a)).
(Step 6) A step in which a second layer of semiconductor chips 12b is laminated on the adhesive layer 1 patterned on the circuit side 18 of the semiconductor chips 12a mounted on the supporting member 13 (FIG. 17(b)).
(Step 7) A step in which the semiconductor chips 12a and 12b are connected to respective external connecting terminals (FIG. 18).

(Step 1) to (step 7) will now be explained in detail.

### (Step 1)

In the semiconductor wafer 8 shown in FIG. 13(a) there are formed a plurality of semiconductor chips 12 partitioned by the dicing lines D. The film adhesive (adhesive layer) 1 is laminated on the circuit side 18 of the semiconductor chip 12 (FIG. 13(b)). A convenient method for laminating the adhesive layer 1 is one in which a film adhesive previously molded into a film is prepared and attached to the semiconductor wafer 8, but it may instead be a method in which spin coating or the like is used to coat the semiconductor wafer 8 with a liquid varnish of the photosensitive adhesive composition, and the coating is heat dried.

### (Step 2)

The adhesive layer 1 is a negative-type photosensitive adhesive capable of alkali development, that exhibits thermocompression bondability for the adherend after it has been patterned by light exposure and development. More specifically, the resist pattern (adhesive pattern) formed by patterning of the adhesive layer 1 by light exposure and development has thermocompression bondability for adherends, such as semiconductor chips and supporting members. The adhesive pattern and the adherend can be bonded by, for example, contact bonding the adherend onto the adhesive pattern with heating if necessary.

The adhesive layer 1 laminated on the semiconductor wafer 8 is irradiated with active light rays (typically ultraviolet rays) via a mask 4 having openings formed at prescribed locations (FIG. 13(c)). The adhesive layer 1 is thus exposed to light in the prescribed pattern.

Following exposure, the sections of the adhesive layer 1 that were not exposed to light are removed by development using an alkali developing solution, so that the adhesive layer 1 is patterned in a manner such that openings 11 are formed (FIG. 14(a)). A positive photosensitive adhesive composition may be used instead of a negative one, in which case the sections of the adhesive layer 1 exposed to light are removed by development.

FIG. 15 is a top view showing the patterned state of an adhesive layer 1. The bonding pads of semiconductor chips 12 are exposed at the openings 11. That is, the patterned adhesive layer 1 is the buffer coat film of the semiconductor chip 12. A plurality of rectangular openings 11 are formed in rows on each semiconductor chip 12. The shapes, arrangement and number of openings 11 are not restricted to those of this embodiment, and they may be appropriately modified in such a manner that the prescribed sections of the bonding pads are exposed. FIG. 14 is an end view of FIG. 15 along line II-II.

### (Step 3)

After patterning, the side of the semiconductor wafer 8 opposite the adhesive layer 1 side is polished to reduce the thickness of the semiconductor wafer 8 to the prescribed thickness (FIG. 14(b)). The polishing is carried out, for example, by attaching a pressure-sensitive adhesive film onto the adhesive layer 1 and fixing the semiconductor wafer 8 on a polishing jig by the pressure-sensitive adhesive film.

### (Step 4)

After polishing, a composite film 5 comprising a die bonding material 30 and dicing tape 40, laminated together, is attached to the side of the semiconductor wafer 8 opposite the adhesive layer 1 side, oriented with the die bonding material 30 contacting the semiconductor wafer 8. The attachment is carried out with heating if necessary.

Next, the semiconductor wafer 8 is diced together with the adhesive layer 1 and composite film 5, along the dicing lines D. This produces a plurality of semiconductor chips 12 each comprising an adhesive layer 1 and a composite film (FIG. 16(a)). The dicing is accomplished using a dicing blade, for example, while the wafer is completely anchored to a frame by the dicing tape 40.

### (Step 5)

Each diced semiconductor chip 12 is then picked up together with the adhesive layer 1 and die bonding material 30 (FIG. 16(b)), and mounted on the supporting member 13 through the die bonding material 30 (FIG. 17(a)).

### (Step 6)

A second semiconductor chip 12b layer is laminated on the adhesive layer 1 on the semiconductor chip 12a mounted on the supporting member 13 (FIG. 17(b)). In other words, the semiconductor chip 12a and the semiconductor chip 12b positioned on its upper layer are bonded by the patterned adhesive layer 1 (buffer coat film) lying between them. The semiconductor chip 12b is bonded at a position such that the openings 11 of the patterned adhesive layer 1 are not blocked. The patterned adhesive layer 1 (buffer coat film) is also formed on the circuit side 18 of the semiconductor chip 12b.

Bonding of the semiconductor chip 12b is accomplished by, for example, a method of thermocompression bonding while heating to a temperature at which the adhesive layer 1 exhibits fluidity. After thermocompression bonding, the adhesive layer 1 is heated if necessary to further promote curing.

### (Step 7)

Next, the semiconductor chip 12a is connected to an external connecting terminal on the supporting member 13 via a wire 14a connected to its bonding pad, while the semiconductor chip 12b is connected to an external connecting terminal on the supporting member 13 via a wire 14b connected to its bonding pad. Next, the stack comprising the semiconductor chips 12a and 12b is sealed with a sealing material 15, to obtain a semiconductor device 200 (FIG. 18).

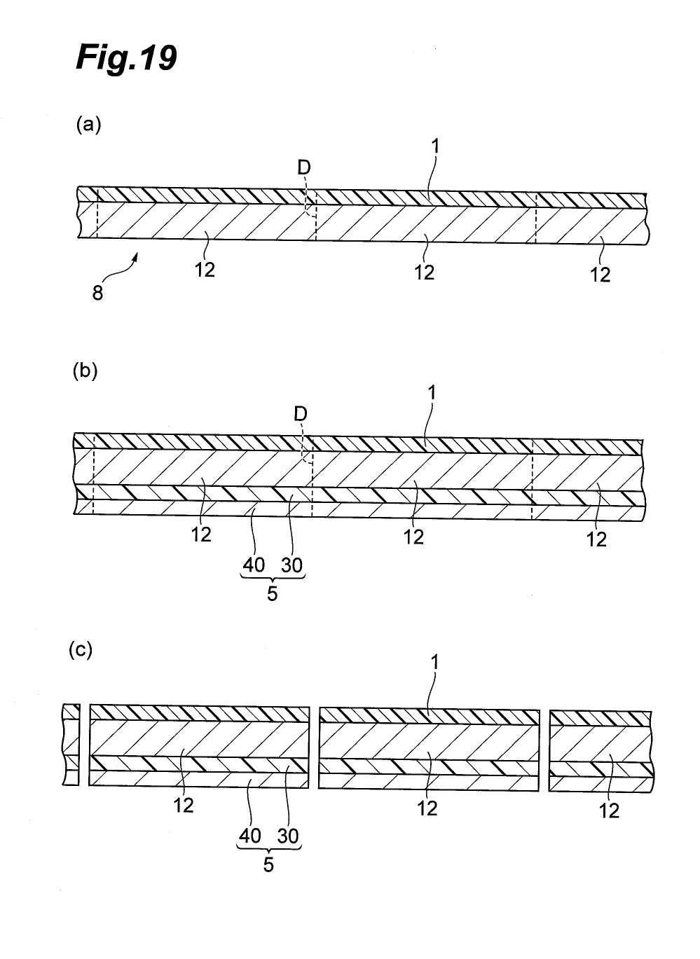

The method for manufacturing a semiconductor device according to the invention is not limited to the embodiments described above, and it may incorporate appropriate modifications that still fall within the gist of the invention. For example, the steps from (step 1) to (step 7) may be reordered as appropriate. As shown in FIG. 19, the semiconductor wafer 8 on which the adhesive layer 1 has been formed may be thinned by polishing and then diced. In this case, the adhesive layer 1 is patterned by exposure and development after dicing, to obtain a stack similar to that shown in FIG. 16(a). Alternatively, the semiconductor wafer that has been thinned by polishing may be diced first, before attachment of the film adhesive 1 and exposure and development thereof. Also, 3 or more semiconductor chips 12 may be stacked. In this case, at least one pair of adjacent semiconductor chips is directly bonded by the patterned adhesive layer 1 (the buffer coat film on the lower layer side).

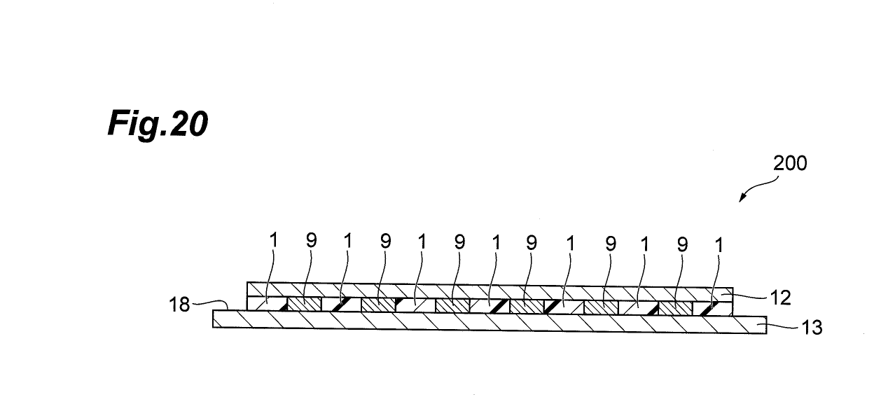

FIG. 20 is an end view showing another embodiment of a semiconductor device according to the invention. The semiconductor device 200 shown in FIG. 20 comprises a supporting member (first adherend) 13 with a connecting terminal (first connected section: not shown), a semiconductor chip (second adherend) 12 with a connecting electrode section (second connected section: not shown), an adhesive layer 1 made of an insulating material, and a conductive layer 9 made of a conductive material. The supporting member 13 has a circuit side 18 opposing the semiconductor chip 12, and it is situated at a prescribed spacing from the semiconductor chip 12. The adhesive layer 1 is formed between the supporting member 13 and semiconductor chip 12 in contact with each, and it has a prescribed pattern. The conductive layer 9 is formed at the sections where the adhesive layer 1 is absent between the supporting member 13 and semiconductor chip 12. The connecting electrode section of the semiconductor chip 12 is electrically connected to the connecting terminal of the supporting member 13 via the conductive layer 9.

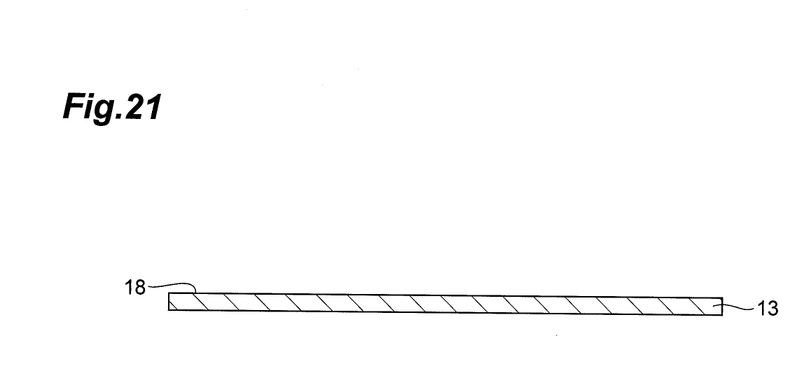

A method for manufacturing the semiconductor device shown in FIG. 20 will now be explained in detail with reference to FIGS. 21 to 25. FIGS. 21 to 25 are end views showing embodiments of a method for manufacturing a semiconductor device according to the invention.

The method for manufacturing a semiconductor device according to this embodiment comprises the following (first step) to (fourth step).

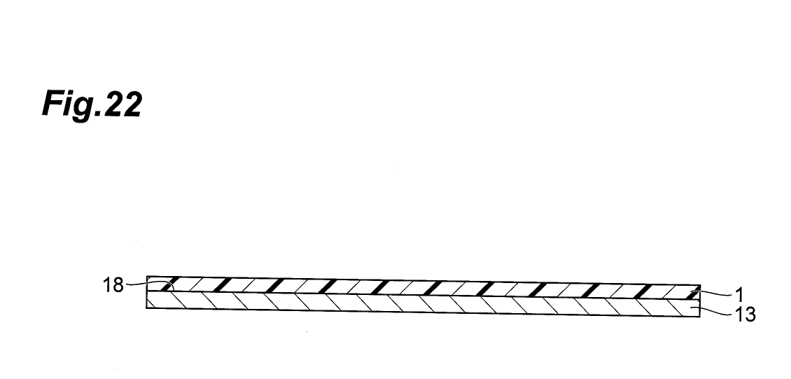

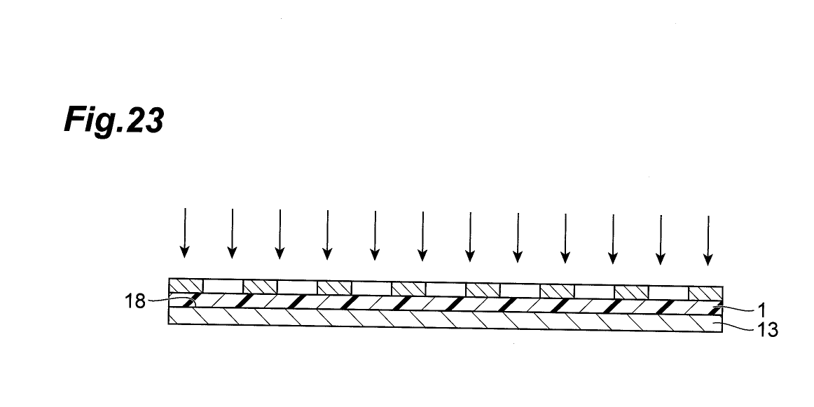

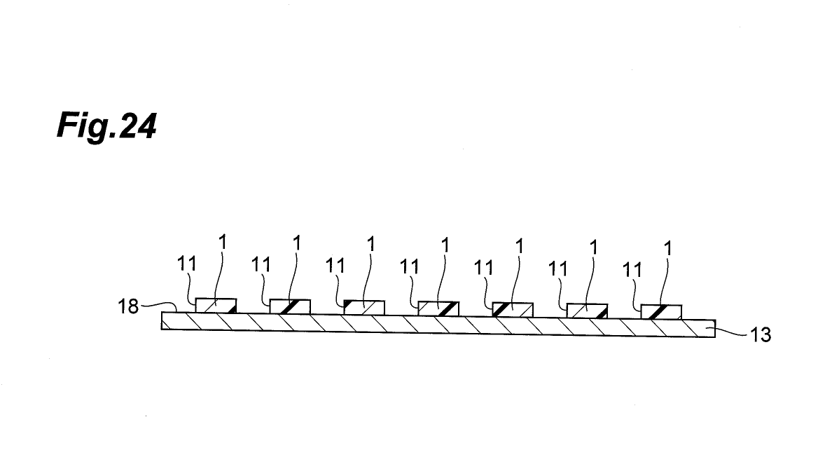

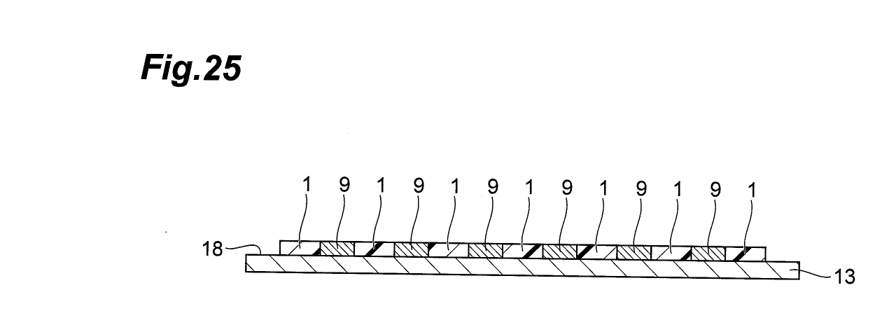

(First step) A step of providing an adhesive layer 1 on a supporting member 13 having a connecting terminal (FIG. 21 and FIG. 22).
(Second step) A step of patterning the adhesive layer 1 by exposure and development so that openings 11 are formed where the connecting terminal is exposed (FIG. 23 and FIG. 24).
(Third step) A step of forming a conductive layer 9 by filling a conductive material into the openings 11 (FIG. 25).
(Fourth step) A step of bonding a semiconductor chip 12 with a connecting electrode section to the adhesive layer 1 side of the stack of the supporting member 13 and the adhesive layer 1, while electrically connecting the connecting terminal of the supporting member 13 and the connecting electrode section of the semiconductor chip 12 via the conductive layer 9 (FIG. 20).

Each of the (first step) to (fourth step) will now be explained in detail.

### (First Step)

An adhesive layer 1 is laminated on the circuit side 18 of the supporting member 13 shown in FIG. 21 (FIG. 22). A convenient laminating method is one in which a film adhesive previously molded into a film is prepared and attached to the supporting member 13, but it may instead be a method in which spin coating or the like is used to coat the supporting member 13 with a liquid varnish containing the photosensitive adhesive composition, and the coating is heat dried.

The photosensitive adhesive composition is a photosensitive adhesive capable of alkali development, that has thermocompression bondability for the adherend after it has been patterned by light exposure and development. More specifically, the resist pattern formed by patterning of the photosensitive adhesive by light exposure and development has thermocompression bondability for adherends such as semiconductor chips and boards. The resist pattern and the adherends can be bonded by, for example, contact bonding the adherends onto the resist pattern with heating if necessary.

### (Second Step)

The adhesive layer 1 formed on the supporting member 13 is irradiated with active light rays (typically ultraviolet rays) through a mask 4 having openings formed at prescribed locations (FIG. 23). The adhesive layer 1 is thus exposed to light in the prescribed pattern.

Following exposure, the sections of the adhesive layer 1 that were not exposed to light are removed by development using an alkali developing solution, so that the adhesive layer 1 is patterned in a manner such that openings 11 are formed where the connecting terminal of the supporting member 13 is exposed (FIG. 24). A positive photosensitive adhesive may be used instead of a negative one, in which case the sections of the adhesive layer 1 exposed to light are removed by development.

A conductive material is filled into the openings 11 of the obtained resist pattern to form a conductive layer 9 (FIG. 25). The method of filling the conductive material may be gravure printing, indenting with a roll, or pressure reduction filling. The conductive material used may be an electrode material made of a metal or metal oxide such as solder, gold, silver, nickel, copper, platinum, palladium or ruthenium oxide, and it may consist of bumps of such metals or, for example, it may comprise at least conductive particles and a resin component. The conductive particles may be, for example, conductive particles made of a metal or a metal oxide of gold, silver, nickel, copper, platinum, palladium or ruthenium oxide, or an organometallic compound. An example of a resin component to be used is the curable resin composition described above, comprising an epoxy resin and its curing agent.

A semiconductor chip 12 is directly bonded onto the adhesive layer 1 of the supporting member 13. The connecting electrode section of the semiconductor chip 12 is electrically connected to the connecting terminal of the supporting member 13 via the conductive layer 9. A patterned adhesive layer (buffer coat film) may be formed on the circuit side of the semiconductor chip 12 opposite the adhesive layer 1 side.

Bonding of the semiconductor chip 12 is accomplished by, for example, a method of thermocompression bonding while heating to a temperature at which the adhesive layer 1 (photosensitive adhesive composition) exhibits fluidity. After thermocompression bonding, the adhesive layer 1 is heated if necessary to further promote curing.

A back side protective film is preferably attached to the circuit side (back side) of the semiconductor chip 12 opposite the adhesive layer 1 side.

The semiconductor device 200 shown in FIG. 20 is obtained by this method. The method for manufacturing a semiconductor device according to the invention is not limited to the embodiments described above, and it may incorporate appropriate modifications that still fall within the gist of the invention.

For example, the adhesive layer 1 is not limited to being formed first on the supporting member 13, and may instead be formed first on the semiconductor chip 12. In this case, the method for manufacturing a semiconductor device comprises, for example, a first step of forming an adhesive layer 1 on a semiconductor chip 12 having a connecting electrode section, a second step of patterning the adhesive layer 1 by light exposure and development so that openings 11 are formed where the connecting electrode section is exposed, a third step of filling a conductive material into the openings 11 to form a conductive layer 9, and a fourth step of directly bonding a supporting member 13 having a connecting terminal to the adhesive layer 1 of the stack comprising the semiconductor chip 12 and the adhesive layer 1, while electrically connecting the connecting terminal of the supporting member 13 to the connecting electrode section of the semiconductor chip 12 via the conductive layer 9.

In this manufacturing method, connection is between the individuated supporting member 13 and semiconductor chip 12, and it is therefore preferred from the viewpoint of facilitating connection between the connecting terminal on the supporting member 13 and the connecting electrode section on the semiconductor chip 12.

The adhesive layer 1 may also be formed first on a semiconductor wafer composed of a plurality of semiconductor chips 12. In this case, the method for manufacturing a semiconductor device comprises, for example, a first step of forming an adhesive layer 1 on a semiconductor wafer composed of a plurality of semiconductor chips 12 with connecting electrode sections, a second step of patterning the adhesive layer 1 by light exposure and development so that openings 11 are formed where the connecting electrode section is exposed, a third step of filling the openings 11 with a conductive material to form a conductive layer 9, a fourth step of directly bonding a wafer-size supporting member 13 having a connecting terminal (a supporting member having approximately the same size as the semiconductor wafer) onto the adhesive layer 1 of the stack comprising the semiconductor wafer and the adhesive layer 1, while electrically connecting the connecting terminal of the supporting member 13 and the connecting electrode section of the semiconductor chip 12 composing the semiconductor wafer, via the conductive layer 9, and a fifth step of dicing the stack of the semiconductor wafer, adhesive layer 1 and supporting member 13 into semiconductor chips 12.

In this manufacturing method, the adhesive layer 1 may be provided on the wafer-size supporting member 13 in the first step, the semiconductor wafer may be directly bonded to the adhesive layer 1 side of the stack comprising the supporting member 13 and the adhesive layer 1 while electrically connecting the connecting terminal of the supporting member 13 with the connecting electrode section of the semiconductor chip 12 composing the semiconductor wafer via the conductive layer 9, in the fourth step, and the stack comprising the semiconductor wafer, the adhesive layer 1 and the supporting member 13 may be diced into semiconductor chips 12 in the fifth step.

The step up to connection of the semiconductor wafer and the supporting member 13 (fourth step) in this manufacturing method is preferred from the viewpoint of working efficiency because it can be carried out with a wafer size. A back side protective film is preferably attached to the circuit side (back side) of the semiconductor wafer opposite the adhesive layer 1 side.

Another method for manufacturing a semiconductor device comprises a first step of forming an adhesive layer 1 on a semiconductor wafer composed of a plurality of semiconductor chips 12 having connecting electrode sections, a second step of patterning the adhesive layer 1 by light exposure and development so that openings 11 are formed where the connecting electrode sections are exposed, a third step of filling the conductive material into the openings 11 to form a conductive layer 9, a fourth step of dicing the stack comprising the semiconductor wafer and the adhesive layer 1 into semiconductor chips 12, and a fifth step of directly bonding a supporting member 13 having a connecting terminal to the adhesive layer 1 side of the stack comprising the individuated semiconductor chips 12 and adhesive layer 1, while electrically connecting the connecting terminal of the supporting member 13 to the connecting electrode sections of the semiconductor chips 12 via the conductive layer 9.

In this manufacturing method, an adhesive layer 1 may be provided on a wafer-size supporting member 13 in the first step, the stack comprising the wafer-size supporting member 13 and the adhesive layer 1 may be diced into semiconductor chips 12 in the fourth step, and the semiconductor chips 12 may be directly bonded to the adhesive layer 1 side of the stack comprising the individuated supporting member 13 and the adhesive layer 1 while electrically connecting the connecting terminal of the supporting member 13 with the connecting electrode sections of the semiconductor chips 12 via the conductive layer 9, in the fifth step.

This manufacturing method is preferred in that the steps from formation of the adhesive layer 1 to filling of the conductive material (third step) are carried out with a wafer size, and the dicing step (fourth step) can be accomplished smoothly.

The film adhesive may also be used to bond together semiconductor wafers or semiconductor chips to form a semiconductor device (semiconductor stack). Through electrodes may also be formed in the stack.

In this case, the method for manufacturing a semiconductor device comprises, for example, a first step of forming an adhesive layer 1 made of a photosensitive adhesive on a first semiconductor chip 12 having a through electrode-connecting electrode section, a second step of patterning the adhesive layer 1 by light exposure and development so that openings 11 are formed where the connecting electrode section is exposed, a third step of filling the conductive material into the openings 11 to form through electrode connections, and a fourth step of directly bonding a second semiconductor chip 12 having connecting electrode sections to the adhesive layer 1 of the stack comprising the first semiconductor chip 12 and the adhesive layer 1, while electrically connecting together the connecting electrode sections of the first and second semiconductor chips 12 via a conductive layer 9. A semiconductor wafer may be used instead of a semiconductor chip in this manufacturing method.

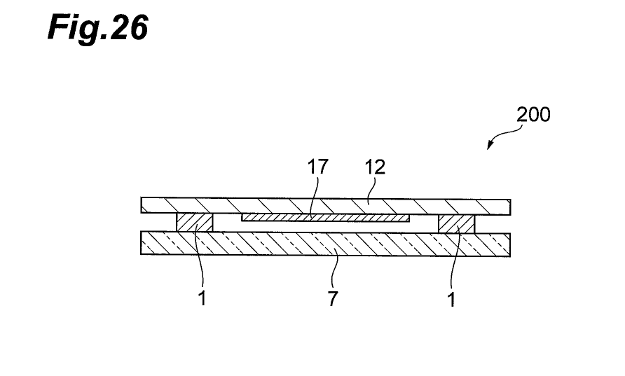

The semiconductor device of the invention may be a solid pickup element such as shown in FIG. 26. FIG. 26 is an end view showing an embodiment of a semiconductor device according to the invention. The semiconductor device (solid pickup element) 200 shown in FIG. 26 comprises a glass panel 7, a semiconductor chip 12, an adhesive layer 1 and an effective picture element region 17. The glass panel 7 and the semiconductor chip 12 are bonded via the patterned adhesive layer 1, and an effective picture element region 17 is formed on the supporting member 13 side of the semiconductor chip 12.

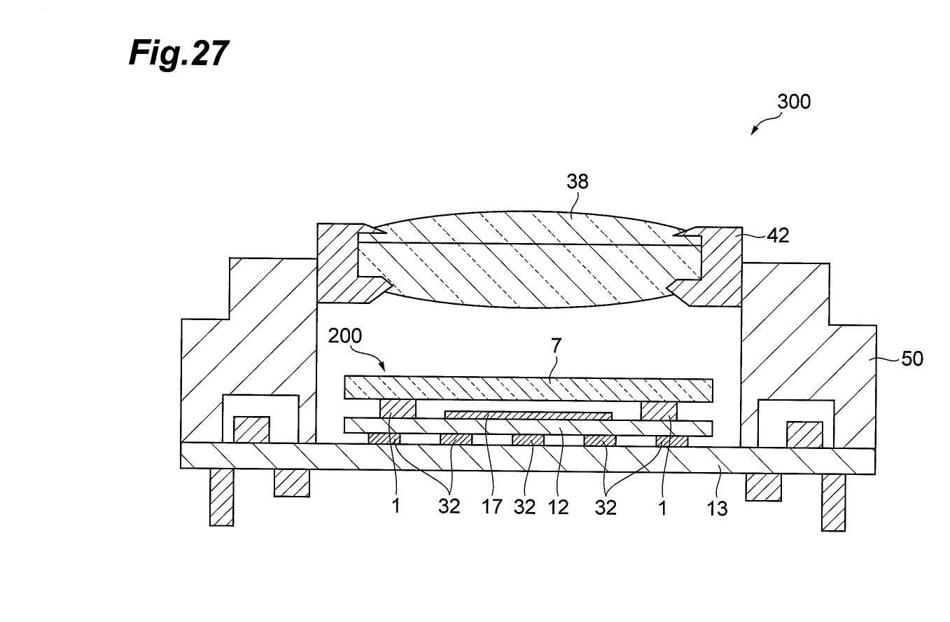

The semiconductor device (solid pickup element) 200 is used, for example, for production of a CMOS sensor such as shown in FIG. 27. FIG. 27 is an end view showing an example of a CMOS sensor employing the semiconductor element shown in FIG. 26 as a solid pickup element. In the CMOS sensor 300 shown in FIG. 27, the semiconductor device 200 is electrically connected to a connecting terminal (not shown) on a semiconductor element-mounting supporting member 13 via a plurality of conductive bumps 32. Instead of a construction in which the semiconductor device 200 is bonded via conductive bumps 32, it may have a construction wherein the semiconductor device 200 is connected to connecting terminals on the semiconductor element-mounting supporting member 13 via conductive wires.

The CMOS sensor 300 has a construction wherein a lens 38 provided at a location directly over the effective picture element region 17 (the side opposite the semiconductor chip 12), side walls 50 provided so as to enclose the semiconductor device 200 together with the lens 38, and a fitting member 42 lying between the lens 38 and side walls 50, in which the lens 38 is fitted, are mounted on the semiconductor element-mounting supporting member 13.

The CMOS sensor 300 is produced by connecting a semiconductor device 200 produced by the method described above with a connecting terminal on the semiconductor element-mounting supporting member 13 and the semiconductor chip 12 via conductive bumps 32, and forming a lens 38, side walls 50 and a fitting member 42 on the semiconductor element-mounting supporting member 13, enclosing the semiconductor device 200.

### EXAMPLES

The present invention will now be explained in greater detail by examples. However, the present invention is not limited to the examples described below.

### <Component (A): Imide Group-Containing Resin>

### (PI-1)

In a 300 mL flask equipped with a stirrer, thermometer, nitrogen-substitution device (nitrogen inlet tube) and moisture receptor-mounted reflux condenser, there were charged 7.32 g (0.02 mol) of the diamine 2,2-bis(3-amino-4-hydroxyphenyl)hexafluoropropane (trade name: “BIS-AP-AF” (molecular weight: 366), product of Central Glass Co., Ltd.), 13.0 g (0.03 mol) of D-400 (trade name: “D-400” (molecular weight: 433), product of BASF), 6.13 g (0.03 mol) of 1,4-butanediol bis(3-aminopropyl)ether (trade name: “B-12”, product of Tokyo Chemical Industry Co., Ltd., molecular weight: 204.3) and 2.485 g (0.01 mol) of BY16-871EG (trade name: “BY16-871EG”, product of Toray/Dow Corning, Inc.), with 80 g of dehydrated NMP (N-methyl-2-pyrrolidone, product of Kanto Kagaku Co., Ltd.) as the solvent, and the mixture was stirred for dissolution of the diamine in the solvent. Next, 31 g (0.1 mol) of 4,4′-oxydiphthalic dianhydride (hereunder abbreviated as “ODPA”) was added to the solution in the flask in small portions at a time while cooling the flask in an ice bath. Upon completion of the addition, the solution was heated to 180° C. while blowing in nitrogen gas and held at that temperature for 5 hours, to obtain an imide group-containing resin (PI-1). GPC measurement of (PI-1) yielded a result of weight-average molecular weight (Mw)=32,000, based on polystyrene. The Tg of (PI-1) was 55° C.

### (PI-2)

In a 300 mL flask equipped with a stirrer, thermometer, nitrogen-substitution device (nitrogen inlet tube) and moisture receptor-mounted reflux condenser there were charged 14.64 g (0.04 mol) of BIS-AP-AF, 17.32 g (0.04 mol) of D-400 and 2.485 g (0.01 mol) of BY16-871EG, with 80 g of NMP as the solvent, and the mixture was stirred for dissolution of the diamine in the solvent.

Next, 31 g (0.1 mol) of ODPA was added to the solution in the flask in small portions at a time while cooling the flask in an ice bath. Upon completion of the addition, the solution was heated to 180° C. while blowing in nitrogen gas and held at that temperature for 5 hours, to obtain an imide group-containing resin (PI-2). GPC measurement of (PI-2) yielded a result of weight-average molecular weight (Mw)=32,000, based on polystyrene. The Tg of (PI-2) was 75° C.

### (PI-3)

In a 300 mL flask equipped with a stirrer, thermometer, nitrogen-substitution device (nitrogen inlet tube) and moisture receptor-mounted reflux condenser there were charged 21.96 g (0.06 mol) of BIS-AP-AF, 8.66 g (0.02 mol) of D-400 and 2.485 g (0.01 mol) of BY16-871EG, with 80 g of NMP as the solvent, and the mixture was stirred for dissolution of the diamine in the solvent.

Next, 31 g (0.1 mol) of ODPA was added to the solution in the flask in small portions at a time while cooling the flask in an ice bath. Upon completion of the addition, the solution was heated to 180° C. while blowing in nitrogen gas and held at that temperature for 5 hours, to obtain an imide group-containing resin (PI-3). GPC measurement of (PI-3) yielded a result of weight-average molecular weight (Mw)=31,000, based on polystyrene. The Tg of (PI-3) was 95° C.

### (PI-4)

In a 300 mL flask equipped with a stirrer, thermometer, nitrogen-substitution device (nitrogen inlet tube) and moisture receptor-mounted reflux condenser there were charged 21.96 g (0.06 mol) of BIS-AP-AF, 8.66 g (0.02 mol) of D-400 and 3.728 g (0.015 mol) of BY16-871EG, with 80 g of NMP as the solvent, and the mixture was stirred for dissolution of the diamine in the solvent.

Next, 27.9 g (0.09 mol) of ODPA and 5.76 g (0.03 mol) of TAA (trimellitic anhydride) were added to the solution in the flask in small portions at a time while cooling the flask in an ice bath. Upon completion of the addition, the solution was heated to 180° C. while blowing in nitrogen gas and held at that temperature for 5 hours, to obtain an imide group-containing resin (PI-4). GPC measurement of (PI-4) yielded a result of weight-average molecular weight (Mw)=20,000, based on polystyrene. The Tg of (PI-4) was 90° C.

### (PI-5)

In a flask equipped with a stirrer, thermometer, nitrogen-substitution device (nitrogen inlet tube) and moisture receptor-mounted reflux condenser there were charged 5.72 g (0.02 mol) of the diamine 3,3′-dicarboxy-4,4′-diaminodiphenylmethane (product of Wakayama Seika, trade name: “MBAA”, molecular weight: 286), 25.98 g (0.06 mol) of “D-400”, 2.48 g (0.01 mol) of “BY16-871EG” and 110 g of NMP as the solvent, and the mixture was stirred for dissolution of the diamine in the solvent.

Next, 31 g (0.1 mol) of ODPA was added to the solution in the flask in small portions at a time while cooling the flask in an ice bath. Upon completion of the addition, the solution was heated to 180° C. while blowing in nitrogen gas and held at that temperature for 5 hours, to obtain an imide group-containing resin (PI-5). GPC measurement of (PI-5) yielded a result of Mw=30,000, based on polystyrene. The Tg of (PI-5) was 45° C.

### (PI-6)

In a flask equipped with a stirrer, thermometer, nitrogen-substitution device (nitrogen inlet tube) and moisture receptor-mounted reflux condenser there were charged 14.3 g (0.05 mol) of the diamine “MBAA”, 12.99 g (0.03 mol) of “D-400”, 3.73 g (0.015 mol) of “BY16-871EG” and 90 g of NMP as the solvent, and the mixture was stirred for dissolution of the diamine in the solvent.

Next, 31 g (0.1 mol) of ODPA was added to the solution in the flask in small portions at a time while cooling the flask in an ice bath. Upon completion of the addition, the solution was heated to 180° C. while blowing in nitrogen gas and held at that temperature for 5 hours, to obtain an imide group-containing resin (PI-6). GPC measurement of (PI-6) yielded a result of Mw=30,000, based on polystyrene. The Tg of (PI-6) was 90° C.

### (PI-7)

In a flask equipped with a stirrer, thermometer, nitrogen-substitution device (nitrogen inlet tube) and moisture receptor-mounted reflux condenser there were charged 8.64 g (0.04 mol) of the diamine 3,3-dihydroxy-4,4-diaminobiphenyl (hereunder, HAB) (product of Wakayama Seika, trade name: “HAB”, molecular weight: 216), 17.32 g (0.04 mol) of “D-400”, 2.48 g (0.01 mol) of “BY16-871EG” and 80 g of NMP as the solvent, and the mixture was stirred for dissolution of the diamine in the solvent.

Next, 31 g (0.1 mol) of ODPA was added to the solution in the flask in small portions at a time while cooling the flask in an ice bath. Upon completion of the addition, the solution was heated to 180° C. while blowing in nitrogen gas and held at that temperature for 5 hours, to obtain an imide group-containing resin (PI-7). GPC measurement of (PI-7) yielded a result of Mw=30,000, based on polystyrene. The Tg of (PI-7) was 85° C.

<Component (D2): Compound with Ethylenic Unsaturated Group and Epoxy Group>

In a 500 mL flask equipped with a stirrer, thermometer and nitrogen substitution device there were charged 178 g (1.0 equivalent) of a liquid high-purity bisphenol A-bisglycidyl ether epoxy resin (product of Tohto Kasei Co., Ltd., trade name: “YD-825GS”, epoxy equivalents: 178 g/eq), 36 g (0.5 equivalent) of acrylic acid, 0.5 g of triphenylphosphine and 0.15 g of hydroquinone, and the mixture was reacted at 100° C. for 7 hours to obtain a compound (D2) having a carbon-carbon double bond and an epoxy group in the molecule. (D2) was titrated with an ethanol solution of potassium hydroxide, and was confirmed to have an acid value of no greater than 0.3 KOHmg/g. (5% mass reduction temperature: 300° C.)

<Photosensitive adhesive composition>

Using the imide group-containing resins (PI-1) to (PI-7) obtained as described above, and a (B) radiation-polymerizable compound, (C) photoinitiator, (D) thermosetting component, (E) peroxide and (F) filler, each of the components was combined in the compositional ratios listed in Table 1 (units: parts by mass), to obtain photosensitive adhesive compositions (adhesive layer-forming varnishes) for Examples 1-8 and Comparative Examples 1-6.

The details for each of the components in Table 1 are as follows.

### (B) Radiation-Polymerizable Compound

M-313: Isocyanuric acid EO-modified di- and triacrylate by Toagosei Co., Ltd. (5% mass reduction temperature: >400° C.)

### (C) Photoinitiator

I-819: Photoinitiator that undergoes photo-discoloration under UV radiation: bis(2,4,6-trimethylbenzoyl)-phenylphosphine oxide by Ciba, Japan (5% mass reduction temperature: 210° C., molecular absorption coefficient at 365 nm: 2300 ml/g·cm)

I-OXE02: Oxime ester group-containing photoinitiator represented by formula (33): ethanone, 1-[9-ethyl-6-(2-methylbenzoyl)-9H-carbazol-3-yl]-,1-(O-acetyloxime) by Ciba, Japan (5% mass reduction temperature: 370° C., molecular absorption coefficient at 365 nm: 7700 ml/g·cm)

### (D) Thermosetting Component

### (D1) Epoxy Resin

YDF-8170C: Bisphenol F-type bisglycidyl ether by Tohto Kasei Co., Ltd. (5% mass reduction temperature: 270° C.)

(D2) Compound with Ethylenic Unsaturated Group and Epoxy Group

### (D3) Phenol Compound

TrisP-PA: Trisphenol compound (α,α,α′-tris(4-hydroxyphenyl)-1-ethyl-4-isopropylbenzene) by Honshu Chemical Industry (5% mass reduction temperature: 350° C.)

### (E) Peroxide

Percumyl D: Dicumyl peroxide by NOF Corp.

### (F) Filler

R-972: Hydrophobic fumed silica (mean particle size: approximately 16 nm) by Nippon Aerosil Co., Ltd.

TABLE 1

| | | Example | | | | | | | | Comp. Ex. | | | | | |
|---|---|---|---|---|---|---|---|---|---|---|---|---|---|---|---|
| | | 1 | 2 | 3 | 4 | 5 | 6 | 7 | 8 | 1 | 2 | 3 | 4 | 5 | 6 |
| A | PI-1 | 100 | — | — | — | — | — | — | — | — | — | — | 100 | 100 | — |
| | PI-2 | — | 100 | 100 | 100 | — | — | 100 | — | — | — | — | — | — | — |
| | PI-3 | — | — | — | — | 100 | — | — | — | — | — | — | — | — | — |
| | P1-4 | — | — | — | — | — | 100 | — | 100 | — | — | — | — | — | — |
| | PI-5 | — | — | — | — | — | — | — | — | 100 | 100 | — | — | — | — |
| | PI-6 | — | — | — | — | — | — | — | — | — | — | 100 | — | — | — |
| | PI-7 | — | — | — | — | — | — | — | — | — | — | — | — | — | 100 |
| B | M-313 | 80 | 80 | 80 | 80 | 80 | 80 | 80 | 80 | 80 | 80 | 80 | 80 | — | 80 |
| C | I-819 | 3 | 3 | 3 | 3 | 3 | 3 | 2 | 2 | 3 | 3 | 3 | 3 | 3 | 3 |
| | I-OXE02 | — | — | — | — | — | — | 1 | 1 | — | — | — | — | — | — |
| D1 | YDF-8170C | 15 | 15 | 15 | 30 | 30 | 30 | 30 | 30 | 15 | 15 | 30 | — | 30 | 30 |
| D2 | | 20 | 20 | — | 40 | 40 | 40 | 40 | 40 | 20 | — | 40 | — | — | 40 |
| D3 | TrisP-PA | 10 | 5 | 5 | 10 | 5 | 5 | 10 | 5 | 10 | 10 | 10 | — | 5 | 10 |
| E | Percumyl D | 1 | 1 | 1 | 1 | 1 | 1 | 1 | 1 | 1 | 1 | 1 | 1 | 1 | 1 |
| F | R-972 | 5 | 5 | 5 | 5 | 5 | 5 | 5 | 5 | 5 | 5 | 5 | 5 | 5 | 5 |

| | | | | | | | | | | | | | | |
|---|---|---|---|---|---|---|---|---|---|---|---|---|---|---|
| Polyimide resin Tg (° C.) | 55 | 75 | 75 | 75 | 95 | 90 | 75 | 90 | 45 | 45 | 90 | 55 | 55 | 85 |
| Attachment property | A | A | A | A | A | A | A | A | A | A | A | A | A | A |
| Pattern formability (solubility) | A | A | A | A | A | A | A | A | C | C | C | A | C | C |
| Pattern formability (L&S) | A | A | A | A | A | A | A | A | B | B | C | A | C | C |
| Sensitivity | B | B | B | B | B | B | A | A | B | B | C | B | C | C |
| Thermocompression | A | A | A | A | A | A | A | A | A | A | A | C | — | — |
| bondability | | | | | | | | | | | | | | |
| Reflow resistance | A | A | C | A | A | A | A | A | A | C | — | — | — | — |
| Hermetic sealability | C | A | A | A | A | A | A | A | C | C | — | — | — | — |
| Minimum melt | <3000 | 9000 | 16000 | 4000 | 15000 | 12000 | 4500 | 13000 | <3000 | 15000 | 10000 | >30000 | <3000 | >30000 |
| viscosity (Pa · s) | | | | | | | | | | | | | | |
| High-temperature | 5.0 | 8.2 | 2.1 | >10 | >10 | >10 | >10 | >10 | 4.0 | 0.5 | >10 | <0.1 | 5.6 | — |
| adhesion (MPa) | | | | | | | | | | | | | | |
| 110° C. Storage elastic | 7 | 28 | 32 | 22 | 100 | 95 | 28 | 105 | 9 | 9 | — | — | — | — |
| modulus (MPa) | | | | | | | | | | | | | | |

### <Adhesive Sheet>

Each of the obtained photosensitive adhesive compositions was coated onto a base (release agent-treated PET film) to a post-drying thickness of 40 μm, and then heated in an oven at 80° C. for 20 minutes and then at 120° C. for 20 minutes, to form an adhesive layer comprising a photosensitive adhesive composition on a base. Thus, adhesive sheets having bases and adhesive layers formed on the bases were obtained.

### <Evaluation Test>

### (Attachment Property)

A silicon wafer (6-inch diameter, thickness: 400 μm) was placed on a support stage, and the adhesive sheet was laminated thereover with the adhesive layer contacting the silicon wafer (the side opposite the support stage), by roll pressing (temperature: 100° C., linear pressure: 4 kgf/cm, feed rate: 0.5 m/min). After peeling off the base (PET film), an 80 μm-thick, 10 mm-wide, 40 mm-long polyimide film (UPILEX, trade name of Ube Industries, Ltd.) was laminated onto the exposed adhesive layer by roll pressing under the same conditions described above. Thus, a sample stack comprising a silicon wafer, an adhesive layer and a polyimide film, laminated in that order, was obtained.

The sample prepared in this manner was subjected to a 90° peel test at room temperature using a rheometer (STROGRAPH E-S (trade name) by Toyo Seiki Laboratories), for measurement of the peel strength between the adhesive layer and the polyimide film. The samples were evaluated for attachment property based on the measurement results, samples with a peel strength of 2 N/cm or greater being evaluated as A, and samples with less than 2 N/cm being evaluated as B. The evaluation results are shown in Table 1.

### (High-Temperature Adhesion)

An adhesive sheet was laminated on a silicon wafer in the same manner as the aforementioned attachment property evaluation test, except that the roll pressing temperature was 60° C. The obtained stack was exposed at 1000 mJ/cm² using a high-precision parallel exposure apparatus (“EXM-1172-B-∞” (trade name) by Orc Manufacturing Co., Ltd.), from the base-attached adhesive sheet side. The base (PET film) was then peeled off, and a conveyor developing machine (Yako Co., Ltd.) was used for 1 minute of spray development with a 2.38 mass % solution of tetramethylammonium hydride (TMAH) as the developing solution, a temperature of 26° C. and a spray pressure of 0.18 MPa, after which it was washed for 6 minutes with purified water at a temperature of 25° C. and a spray pressure of 0.02 MPa, and dried at 120° C. for 1 minute. A cured layer composed of the cured photosensitive adhesive composition was thus formed on the silicon wafer.

The obtained stack comprising the silicon wafer and cured layer was individuated into sizes of 3 mm×3 mm. An individuated stack was dried on a hot plate at 120° C. for 10 minutes, and then laminated on a glass panel (10 mm×10 mm×0.55 mm) with the cured layer contacting the glass panel, and contact bonded at 150° C. for 10 seconds while pressing at 2 kgf. A sample stack comprising a silicon wafer, a cured layer and a glass panel, laminated in that order, was thus obtained.

The obtained sample was heated in an oven at 180° C. for 3 hours, and further heated on a heating plate at 260° C. for 10 seconds, after which a “Dage-4000” (trade name) shear adhesion tester was used for measurement of the adhesive force. The measurement results are shown in Table 1.

### (110° C. Storage Elastic Modulus)

A polytetrafluoroethylene (trade name: “Teflon”) sheet (Teflon sheet) was placed on a support stage, and the adhesive sheet was laminated thereover by roll pressing (temperature: 60° C., linear pressure: 4 kgf/cm, feed rate: 0.5 m/min). The obtained stack was exposed at 1000 mJ/cm² using a high-precision parallel exposure apparatus (“EXM-1172-B-∞” (trade name) by Orc Manufacturing Co., Ltd.), from the base-attached adhesive sheet side. The base (PET film) was then peeled off, and a conveyor developing machine (Yako Co., Ltd.) was used for 1 minute of exposure with a 2.38 mass % solution of tetramethylammonium hydride (TMAH) as the developing solution, a temperature of 26° C. and a spray pressure of 0.18 MPa, after which it was washed for 6 minutes with purified water at a temperature of 25° C. and a spray pressure of 0.02 MPa. The obtained film was laminated by roll pressing (temperature: 100° C., linear pressure: 4 kgf/cm, feed rate: 0.5 m/min) to a thickness of 80 μm, to obtain a sample stack having the structure: Teflon sheet, adhesive layer, Teflon sheet. After peeling off the Teflon sheet on one side, it was heated in an oven at 180° C. for 3 hours. The heated sample was cut into 5 mm-wide strips, and an “RSA-2” (trade name) viscoelasticity analyzer by Rheometrix was used for measurement under conditions with a temperature-elevating rate of 5° C./min, a frequency of 1 Hz and a measuring temperature of −50-300° C., to obtain the 110° C. storage elastic modulus.

### (Pattern Formability (Solubility))

An adhesive sheet was laminated on a silicon wafer in the same manner as the aforementioned high-temperature adhesion evaluation test. The obtained stack was exposed to light in the same manner as the test described above, from the base-attached adhesive sheet side through a negative pattern mask (“No.G-2” (trade name) by Hitachi Chemical Co., Ltd.). After then allowing it to stand on a hot plate, in the same manner as the test described above, the base was removed and the stack was immersed for 5 minutes in a 2.38 mass % tetramethylammonium hydride (TMAH) aqueous solution, upon which an evaluation of (A) was assigned if a pattern was formed while the unexposed sections dissolved, and an evaluation of (C) was assigned if a pattern was formed while the unexposed sections peeled off as a film or if no pattern formation was observed.

### (Pattern Formability (L&S))

An adhesive sheet was laminated on a silicon wafer in the same manner as the aforementioned high-temperature adhesion evaluation test. Next, a photomask (PHOTOTECH 41 step density tablet (trade name) by Hitachi Chemical Co., Ltd.), commonly known as a step tablet, was placed on the base (PET film) as a negative pattern photomask, in such a manner for decreasing light transmittance in a stepwise manner, and exposed at 1000 mJ/cm² with a high-precision parallel exposure apparatus (“EXM-1172-B-∞” (trade name) by Orc Manufacturing Co., Ltd.), and then allowed to stand on a hot plate at 80° C. for approximately 30 seconds.

The base (PET film) was then removed, and a conveyor developing machine (Yako Co., Ltd.) was used for spray development with a 2.38 mass % solution of tetramethylammonium hydride (TMAH) as the developing solution, a temperature of 26° C. and a spray pressure of 0.18 MPa, after which it was washed with purified water at a temperature of 23° C. and a spray pressure of 0.02 MPa. After development, the number of steps of the step tablet of the photocured film formed on the silicon wafer was counted to evaluate the photosensitivity of the adhesive sheet. Samples with 25 or more remaining steps were evaluated as A, samples with fewer than 25 steps were evaluated as B, and samples wherein no pattern formation was possible were evaluated as C, based on the measurement results. The results are shown in Table 1.

### <Measurement of Minimum Melt Viscosity>

The adhesive sheets obtained in Examples 1-8 and Comparative Examples 1-5 were each laminated on a Teflon sheet by pressing with a roll (temperature: 60° C., linear pressure: 4 kgf/cm, feed rate: 0.5 m/min), with the adhesive layer on the Teflon sheet side. Each stack was then exposed to 1000 mJ/cm² with a high-precision parallel exposure apparatus. The base (PET film) was then removed, and the obtained sheet was subjected to spray development for 1 minute at a temperature of 26° C. and a spray pressure of 0.18 MPa, using a conveyor developing machine (Yako Co., Ltd.), with a 2.38 mass % solution of tetramethylammonium hydride (TMAH) as the developing solution, after which it was washed for 3 minutes with purified water at a temperature of 25° C. and a spray pressure of 0.02 MPa. It was then laminated at 80° C. to a thickness of about 200 μm, and cut out to a size of 10 mm×10 mm. The Teflon sheet on one side of the obtained sample was peeled off and the stack was heated at 120° C. for 10 minutes, and then measured using an ARES viscoelasticity measuring apparatus (product of Rheometrix Scientific F.E.). The measuring plate was a parallel plate with a diameter of 8 mm, and the measuring conditions were set to a temperature increase of 5° C./min and a frequency of 1 Hz. The minimum value of the melt viscosity at 50° C.-200° C. was defined as the minimum melt viscosity. The results are shown in Table 1.

### (Thermocompression Bondability)

An adhesive pattern of a photosensitive adhesive composition was formed on a silicon wafer in the same manner as the aforementioned pattern formability evaluation test, except that the roll pressing temperature was 60° C., and a frame-like 6-inch sized mask pattern (hollow section: 2 mm, line width: 0.5 mm) was used instead of the negative pattern mask.

After drying on a hot plate at 120° C. for 10 minutes, a glass panel (15 mm×40 mm×0.55 mm) was laminated on the side of the formed adhesive pattern opposite the silicon wafer side, and contact bonding was performed at 150° C. for 10 minutes while pressing at 0.5 MPa, to obtain a sample stack comprising the silicon wafer, adhesive pattern and glass panel, laminated in that order.

The obtained sample was observed and the thermocompression bondability was evaluated, assigning an evaluation of A if the unbonded sections (voids) were no greater than 20% of the bonding area between the glass panel and the adhesive pattern, and an evaluation of C if they were 20% or greater. The evaluation results are shown in Table 1.

### (Reflow Resistance)

In the same manner as the aforementioned thermocompression bondability evaluation test, a sample stack comprising the silicon wafer, adhesive pattern and glass panel, laminated in that order, was obtained. The obtained sample was heated in an oven at 180° C. for 3 hours. The heated sample was treated for 168 hours under conditions with a temperature of 85° C. and a humidity of 60% and then placed in an environment with a temperature of 25° C. and a humidity of 50%, after which it was subjected to IR reflow at 250° C. for 10 seconds and the presence of peeling was observed with a microscope (magnification: 15×). The reflow resistance was evaluated, as A for samples in which no peeling was observed, and C for samples in which peeling was observed. The evaluation results are shown in Table 1.

### (Hermetic Sealability)

In the same manner as the aforementioned reflow evaluation test, the sample stack was heated in an oven at 180° C. for 3 hours. The heated sample was treated for 48 hours under conditions with a temperature of 110° C. and a humidity of 85% using an accelerated life tester (HASTEST PC-422R8, product of Hirayama Manufacturing Corp.), and was then allowed to stand in the apparatus until the temperature reached 30° C. It was then placed in an environment with a temperature of 25° C. and a humidity of 50%, and condensation of the glass interior of the sample or peeling of the adhesive was observed with a microscope. The hermetic sealability at 110° C. was evaluated, assigning an evaluation of A for samples in which condensation and/or peeling was not observed, and an evaluation of C for samples in which condensation and/or peeling was observed. The evaluation results are shown in Table 1.

### INDUSTRIAL APPLICABILITY

The photosensitive adhesive composition of the invention is sufficiently excellent in terms of all the properties of attachment, high-temperature adhesion, pattern formability, thermocompression bondability, heat resistance and humidity resistance, and it can therefore be suitably used as an adhesive for production of a high-definition semiconductor package. In addition, a film adhesive or adhesive sheet of the invention, when applied onto an adherend or supporting member such as a board, glass or silicon wafer, has more excellent positioning precision than when using a liquid resin composition and can improve patterning resolution by exposure, while it has low-temperature thermocompression bondability with pattern-formed adherends such as boards, glass and semiconductor elements, as well as excellent post-thermosetting heat resistance, and it is therefore suitable for protection of semiconductor elements, optical elements and solid pickup elements, or as an adhesive or buffer coat to be applied in fine bonding regions.

### EXPLANATION OF SYMBOLS

1: Film adhesive (adhesive layer), 1a: adhesive pattern, 2: cover film, 3: base, 4: mask, 5: composite film, 6: pressure-sensitive adhesive layer, 7: glass panel, 8: semiconductor wafer, 9: conductive layer, 11: opening, 12, 12a, 12b: semiconductor elements (semiconductor chips), 13: semiconductor element-mounting supporting member (supporting member), 14, 14a, 14b: wires, 15: sealing material, 16: terminal, 17: effective picture element region, 18: circuit side, 20: semiconductor wafer with adhesive layer, 30: die bonding material, 32: conductive bump, 38: lens, 40: dicing tape, 42: fitting member, 50: side wall, 100: adhesive sheet, 200: semiconductor device, 300: CMOS sensor, D: dicing line.

1. A photosensitive adhesive comprising (A) an imide group-containing resin with a fluoroalkyl group, (B) a radiation-polymerizable compound, (C) a photoinitiator and (D) a thermosetting component.

2. The photosensitive adhesive according to claim 1, wherein the (A) imide group-containing resin with a fluoroalkyl group has a Tg of no higher than 180° C.

3. The photosensitive adhesive according to claim 1, wherein the (A) imide group-containing resin with a fluoroalkyl group also contains an alkali-soluble group.

4. The photosensitive adhesive according to claim 1, wherein the (A) imide group-containing resin with a fluoroalkyl group is an imide group-containing resin obtained by reacting a diamine including a diamine with a phenolic hydroxyl group at 5 mol % or greater of the total diamine, with a tetracarboxylic dianhydride.

5. The photosensitive adhesive according to claim 4, wherein the diamine with a phenolic hydroxyl group includes a diamine represented by the following formula (6).

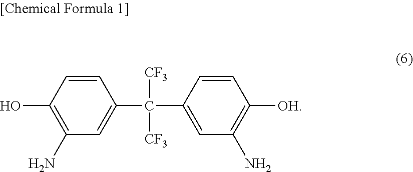

6. The photosensitive adhesive according to claim 1, wherein the (A) imide group-containing resin with a fluoroalkyl group is an alkali-soluble resin.

7. The photosensitive adhesive according to claim 1, wherein the (D) thermosetting component contains (D1) an epoxy resin.

8. The photosensitive adhesive according to claim 1, wherein the (D) thermosetting component further contains (D2) a compound with an ethylenic unsaturated group and an epoxy group.

9. The photosensitive adhesive according to claim 1, wherein the (D) thermosetting component further contains (D3) a phenol compound.

10. The photosensitive adhesive according to claim 1, which further comprises (E) a peroxide.

11. The photosensitive adhesive according to claim 1, which further comprises (F) a filler.

12. A film adhesive obtained by forming a photosensitive adhesive according to claim 1 into a film shape.

13. An adhesive sheet comprising a base, and an adhesive layer composed of a film adhesive according to claim 12 formed on the base.

14. An adhesive pattern that is obtained by exposing an adhesive layer composed of a film adhesive according to claim 12 laminated on an adherend, and developing the exposed adhesive layer with an alkali developing solution.

15. A semiconductor wafer with an adhesive layer, comprising a semiconductor wafer and an adhesive layer composed of a film adhesive according to claim 12, laminated on the semiconductor wafer.

16. A semiconductor device having a structure wherein semiconductor elements, and/or a semiconductor element and a semiconductor element-mounting supporting member, are bonded using a photosensitive adhesive according to claim 1.

17. The semiconductor device according to claim 16, wherein the semiconductor element-mounting supporting member is a transparent base.
